(19) United States
(12) Patent Application Publication
(10) Pub. No.: US 2023/0301057 A1
(43) Pub. Date: Sep. 21, 2023

(54) MEMORY DEVICE INCLUDING PILLAR-SHAPED SEMICONDUCTOR ELEMENT

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 18/322,198

(22) Filed: May 23, 2023

Related U.S. Application Data
(63) Continuation-in-part of application No. 17/478,282, filed on Sep. 17, 2021.
Application No. 17/478,282 is a continuation of application No. PCT/JP2020/048952, filed on Dec. 25, 2020.
Application No. PCT/JP2020/048952 is a continuation-in-part of application No. PCT/JP2021/004051, filed on Feb. 4, 2021.

(51) Int. Cl. H10B 12/00; G11C 5/06; G11C 11/4096; H01L 29/78; H01L 29/49; H01L 29/51

(52) U.S. Cl. CPC H10B 12/20; G11C 5/063; G11C 11/4096; H01L 29/7841; H01L 29/4966; H01L 29/517

(57) ABSTRACT

An N⁺ layer 11a connected to a source line SL, N⁺ layers 13a and 13c connected to a bit line BL1, and N⁺ layers 13b and 13d connected to a bit line BL2 are formed at both ends of Si pillars 12a to 12d standing on a substrate 10 in a perpendicular direction. Also formed are a TiN layer 18 surrounding a gate HfO₂ layer surrounding the Si pillars 12a to 12d, the TiN layer 18 extending between the Si pillars 12a to 12d and connected to a plate line PL, and TiN layers 26a and 26b surrounding a gate HfO₂ layer 17b surrounding the Si pillars 12a to 12d, the TiN layer 26a extending between the Si pillars 12a and 12b and connected to a word line WL1, the TiN layer 26b extending between the Si pillars 12c and 12d and connected to a word line WL2. The voltages applied to the source line SL, the plate line PL, the word lines WL1 and WL2, and the bit lines BL1 and BL2 are controlled to perform a data holding operation of holding a group of holes generated by an impact ionization phenomenon or a gate-induced drain leakage current in any or all of the Si pillars 12a to 12d and a data erase operation of removing the group of holes from the Si pillars 12a to 12d.

### CROSS REFERENCES TO RELATED APPLICATIONS

The present application is a continuation-in-part application of U.S. application Ser. No. 17/478,282 filed Sep. 17, 2021 which is a continuation of PCT/JP2020/048952, filed on Dec. 25, 2020. This application is also a continuation-in-part application of PCT/JP2021/004051, filed Feb. 4, 2021, the entire contents of each of which are incorporated herein by reference.

### BACKGROUND OF THE INVENTION

### 1. Field of the Invention

The present invention relates to memory devices including pillar-shaped semiconductor elements.

### 2. Description of the Related Art

Recently, there has been a need for a higher degree of integration and a higher performance of memory elements in large-scale integration (LSI) technology development.

A typical planar metal-oxide-semiconductor (MOS) transistor includes a channel extending in a direction parallel to an upper surface of a semiconductor substrate. In contrast, a surrounding gate transistor (SGT) includes a channel extending in a direction perpendicular to an upper surface of a semiconductor substrate (see, for example, Japanese Unexamined Patent Application Publication No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Thus, SGTs allow for higher densities of semiconductor devices than planar MOS transistors. SGTs can be used as select transistors to achieve higher degrees of integration of devices such as dynamic random-access memory (DRAM; see, for example, H. Chung, H. Kim, H. Kim, K. Kim, S. Kim, K. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference (2011)), which has a capacitor connected thereto; phase-change memory (PCM; see, for example, H. S. Philip Wong, S. Raoux, S. Kim, Jiale Liang, J. R. Reifenberg, B. Rajendran, M. Asheghi, and K. E. Goodson: “Phase Change Memory,” Proceeding of IEEE, Vol. 98, No. 12, December, pp. 2201-2227 (2010)) and resistive random-access memory (RRAM; see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3 V,” IEDM (2007)), which have a variable-resistance element connected thereto; and magneto-resistive random-access memory (MRAM; see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015) and M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010)), in which the resistance changes as the magnetic spin orientation changes with current. There are also, for example, DRAM memory cells, which are composed of a single MOS transistor without a capacitor (see J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012)). The present application relates to a dynamic flash memory, which can be composed only of a MOS transistor without a variable-resistance element or a capacitor.

FIGS. 7A to 7D illustrate the write operation of a DRAM memory cell composed of a single MOS transistor without a capacitor as mentioned above, FIGS. 8A and 8B illustrate a problem with its operation, and FIGS. 9A to 9C illustrate its read operation (see J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI,” IEEE JSSC, Vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, and A. Nitayama: “Floating Body RAM Technology and its Scalability to 32 nm Node and Beyond,” IEEE IEDM (2006); and E. Yoshida: “A Capacitorless 1T-DRAM Technology Using Gate-Induced Drain-Leakage (GIDL) Current for Low-Power and High-Speed Embedded Memory,” IEEE IEDM (2006)).

FIGS. 7A to 7D illustrate the write operation of the DRAM memory cell. FIG. 7A illustrates a “1” written state. Here, the memory cell is formed on a silicon-on-insulator (SOI) substrate 100 and is composed of a source N⁺ layer 103 (a semiconductor region containing a high concentration of a donor impurity is hereinafter referred to as “N⁺ layer”) having a source line SL connected thereto, a drain N⁺ layer 104 having a bit line BL connected thereto, a gate conductive layer 105 having a word line WL connected thereto, and a floating body 102 of a MOS transistor 110a; that is, the DRAM memory cell is composed of a single MOS transistor 110a without a capacitor. A SiO₂ layer 101 of the SOI substrate 100 is disposed directly under and in contact with the floating body 102. When “1” is written in the memory cell composed of the single MOS transistor 110a, the MOS transistor 110a is operated in the saturation region. Specifically, an electron channel 107 extending from the source N⁺ layer 103 has a pinch-off point 108 and does not reach the drain N⁺ layer 104 having the bit line BL connected thereto. When the MOS transistor 110a is operated such that both the bit line BL connected to the drain N⁺ layer 104 and the word line WL connected to the gate conductive layer 105 are set to a high voltage and the gate voltage is about half the drain voltage, the maximum electric field intensity is reached at the pinch-off point 108 near the drain N⁺ layer 104. As a result, accelerated electrons flowing from the source N⁺ layer 103 toward the drain N⁺ layer 104 collide with the Si lattice, and electron-hole pairs are generated by the kinetic energy lost in the collision. Most of the generated electrons (not illustrated) reach the drain N⁺ layer 104. In addition, an extremely small proportion of very hot electrons traverse the gate oxide film 109 to reach the gate conductive layer 105. Holes 106 generated at the same time charge the floating body 102. In this case, the generated holes contribute as additional majority carriers since the floating body 102 is P-type Si. When the floating body 102 is filled with the generated holes 106, and the voltage of the floating body 102 is higher than that of the source N⁺ layer 103 by Vb or more, additional generated holes are discharged to the source N⁺ layer 103. Here, Vb is the built-in voltage of the PN junction between the source N⁺ layer 103 and the P layer forming the floating body 102, and is about 0.7 V. FIG. 7B illustrates a situation in which the floating body 102 has been charged to saturation with the generated holes 106.

Next, the “0” write operation of the memory cell 110 will be described with reference to FIG. 7C. A memory cell 110a having “1” written therein and a memory cell 110b having “0” written therein are randomly present for the common select word line WL. FIG. 7C illustrates a situation in which a “1” written state is rewritten to a “0” written state. During “0” writing, the voltage of the bit line BL is negatively biased so that the PN junction between the drain N⁺ layer 104 and the P layer forming the floating body 102 is forward-biased. As a result, the holes 106 generated in the floating body 102 in advance in the previous cycle flow into the drain N⁺ layer 104 connected to the bit line BL. Upon completion of the write operation, two memory cell states are obtained, i.e., the memory cell 110a (FIG. 7B) filled with the generated holes 106 and the memory cell 110b (FIG. 7C) having the generated holes 106 discharged therefrom. The potential of the floating body 102 of the memory cell 110a filled with the holes 106 is higher than that of the floating body 102 having no generated holes therein. Thus, the threshold voltage of the memory cell 110a is lower than the threshold voltage of the memory cell 110b. This situation is illustrated in FIG. 7D.

Next, a problem with the operation of the memory cell composed of a single MOS transistor will be described with reference to FIGS. 8A and 8B. As illustrated in FIG. 8A, the capacitance C_{FB} of the floating body 102 is the sum of the capacitance C_{WL} between the gate having the word line connected thereto and the floating body 102, the junction capacitance C_{SL} of the PN junction between the source N⁺ layer 103 having the source line connected thereto and the floating body 102, and the junction capacitance C_{BL} of the PN junction between the drain N⁺ layer 104 having the bit line connected thereto and the floating body 102, as expressed by:

C_{FB}=C_{WL}+C_{BL}+C_{SL} (1)

Hence, when the word line voltage V_{WL} oscillates during writing, it also affects the voltage of the floating body 102, which serves as the storage node (contact) of the memory cell. This situation is illustrated in FIG. 8B. As the word line voltage V_{WL} increases from 0 V to V_{ProgWL} during writing, the voltage V_{FB} of the floating body 102 increases from a voltage V_{FB1} in the initial state before the change in word line voltage to V_{FB2} due to capacitive coupling with the word line. The change in voltage ΔV_{FB} is expressed by:

$$\begin{matrix}Δ {V}_{F B} = {V}_{F B 2} - {V}_{F B 1} \\ = {C}_{W L} / ( {C}_{WL} + {C}_{BL} + {C}_{SL} ) \times {V}_{ProgWL}\end{matrix} \qquad ( 2 )$$

### Here,

β=C_{WL}/C_{WL}+C_{BL}+C_{SL}) (3)

where β is referred to as coupling rate. In this memory cell, C_{WL} has a large contribution ratio, for example, C_{WL}:C_{BL}:C_{SL}=8:1:1. In this case, β=0.8. For example, when the word line transitions from 5 V during writing to 0 V upon completion of writing, the floating body 102 is subjected to oscillation noise, i.e., 5 V×β=4 V, due to capacitive coupling between the word line and the floating body 102. This causes a problem in that there is an insufficient margin of potential difference between the “1” potential and “0” potential of the floating body 102 during writing.

FIGS. 9A to 9C illustrate the read operation. FIG. 9A illustrates a “1” written state, and FIG. 9B illustrates a “0” written state. In practice, however, even if Vb has been written in the floating body 102 by “1” writing, the floating body 102 is lowered to a negative bias when the word line returns to 0 V upon completion of writing. When “0” is written, the floating body 102 is further negatively biased. Thus, there is an insufficient margin of potential difference between “1” and “0” during writing. This insufficient margin of operation is a considerable problem with this DRAM memory cell. In addition, it is desirable to achieve a higher density of DRAM memory cells.

A capacitorless one-transistor DRAM (gain cell) configured as a memory device including an SGT has a problem in that, when the word line potential oscillates during data reading and writing, it is directly transmitted as noise to the floating body of the SGT because of large capacitive coupling between the word line and the SGT body. This causes the problem of erroneous reading and erroneous rewriting of stored data and thus makes it difficult to put capacitorless one-transistor DRAMs (gain cells) to practical use. In addition to solving the above problem, there is a need for a higher density of DRAM memory cells.

### SUMMARY OF THE INVENTION

To solve the above problems, a memory device including a pillar-shaped semiconductor element according to the present invention includes first to fourth semiconductor pillars standing on a substrate in a perpendicular direction, the first and second semiconductor pillars being disposed adjacent to each other on a first line in plan view, the third and fourth semiconductor pillars being disposed adjacent to each other on a second line extending parallel to the first line in plan view; a first impurity region connected to bottom portions of the first to fourth semiconductor pillars; a gate insulating layer surrounding the first to fourth semiconductor pillars in the perpendicular direction; a first gate conductor layer surrounding the gate insulating layer and extending between the first to fourth semiconductor pillars; a second gate conductor layer surrounding the gate insulating layer, the second gate conductor layer being adjacent to the first gate conductor layer in the perpendicular direction and extending between the first semiconductor pillar and the second semiconductor pillar on the first line; a third gate conductor layer surrounding the gate insulating layer, the third gate conductor layer being adjacent to the first gate conductor layer in the perpendicular direction, being located at the same height as the second gate conductor layer, and extending between the third semiconductor pillar and the fourth semiconductor pillar on the second line; second impurity regions in top portions of the first to fourth semiconductor pillars; a first wiring conductor layer connected to the second impurity regions in the top portions of the first semiconductor pillar and the third semiconductor pillar; and a second wiring conductor layer connected to the second impurity regions in the top portions of the second semiconductor pillar and the fourth semiconductor pillar, wherein voltages applied to the first gate conductor layer, the second gate conductor layer, the third gate conductor layer, the first impurity region, and the second impurity regions are controlled to perform a data write operation, a data read operation, and a data erase operation (first aspect).

In the first aspect, in plan view, a first length between two opposing points of intersection of two outer periphery lines of the gate insulating layer surrounding the first semiconductor pillar and the second semiconductor pillar and the first line may be smaller than a second length between two opposing points of intersection of two outer periphery lines of the gate insulating layer surrounding the first semiconductor pillar and the third semiconductor pillar and a third line passing through centers of the first semiconductor pillar and the third semiconductor pillar; the second length may be greater than twice a third length that is a thickness of the first gate conductor layer surrounding the first semiconductor pillar on the third line; and the first length may be smaller than twice the third length (second aspect).

In the first aspect, a wiring line connected to the first impurity region may be a source line; a wiring line connected to the second impurity regions may be a bit line; when one of a wiring line connected to the first gate conductor layer and a wiring line connected to the second gate conductor layer is a word line, the other of the wiring line connected to the first gate conductor layer and the wiring line connected to the second gate conductor layer may be a first drive control line; and voltages applied to the source line, the bit line, the first drive control line, and the word line may be controlled to perform the data write operation, the data read operation, and the data erase operation (third aspect).

In the first aspect, a first gate capacitance between the first gate conductor layer and the first semiconductor pillar may be greater than a second gate capacitance between the second gate conductor layer and the first semiconductor pillar (fourth aspect).

In the first aspect, a first void may be present between the second gate conductor layer and the third gate conductor layer in plan view (fifth aspect).

In the first aspect, a second void may be present between the first wiring conductor layer and the second wiring conductor layer (sixth aspect).

In the first aspect, the gate insulating layer may extend between the side surfaces of the first to fourth semiconductor pillars, the first gate conductor layer, the second gate conductor layer, and the third gate conductor layer (seventh aspect).

In the first aspect, in plan view, both a first length between two opposing points of intersection of two outer periphery lines of the gate insulating layer surrounding the first semiconductor pillar and the second semiconductor pillar and the first line and a second length between two opposing points of intersection of two outer periphery lines of the gate insulating layer surrounding the first semiconductor pillar and the third semiconductor pillar and a third line passing through centers of the first semiconductor pillar and the third semiconductor pillar may be greater than twice a third length that is a thickness of the first gate conductor layer surrounding the first semiconductor pillar on the third line (eighth aspect).

In the eighth aspect, in plan view, the second gate conductor layer may include a first region surrounding the first semiconductor pillar and the second semiconductor pillar at equal width and a second region extending between the first semiconductor pillar and the second semiconductor pillar on the first line, and in plan view, the third gate conductor layer may include a third region surrounding the third semiconductor pillar and the fourth semiconductor pillar at equal width and a fourth region extending between the third semiconductor pillar and the fourth semiconductor pillar on the second line (ninth aspect).

In the first aspect, the first gate conductor layer, the second gate conductor layer, the third gate conductor layer, the first impurity region, and the second impurity regions may be configured such that the voltages applied to the first gate conductor layer, the second gate conductor layer, the third gate conductor layer, the first impurity region, and the second impurity regions are controlled to perform a data write operation of holding a group of holes generated by an impact ionization phenomenon or a gate-induced drain leakage current in any or all of the first to fourth semiconductor pillars, and the voltages applied to the first gate conductor layer, the second gate conductor layer, the third gate conductor layer, the first impurity region, and the second impurity regions are controlled to perform a data erase operation of removing the group of holes from any or all of the first to fourth semiconductor pillars (tenth aspect).

In the first aspect, one or both of the first gate conductor layer and the second and third gate conductor layers may be split into a plurality of segments in plan view (eleventh aspect).

In the first aspect, the first gate conductor layer may be split into a plurality of segments in the perpendicular direction (twelfth aspect).

In the first aspect, the second gate conductor layer and the third gate conductor layer may be split into a plurality of segments at the same height in the perpendicular direction (thirteenth aspect).

### BRIEF DESCRIPTION OF THE DRAWINGS

FIG. 1 illustrates the structure of a memory device including an SGT according to a first embodiment;

FIGS. 2A, 2B, and 2C illustrate the erase operation mechanism of the memory device including an SGT according to the first embodiment;

FIGS. 3A, 3B, and 3C illustrate the write operation mechanism of the memory device including an SGT according to the first embodiment;

FIGS. 4AA, 4AB, and 4AC illustrate the read operation mechanism of the memory device including an SGT according to the first embodiment;

FIGS. 4BD, 4BE, 4BF, and 4BG illustrate the read operation mechanism of the memory device including an SGT according to the first embodiment;

FIGS. 5AA, 5AB, and 5AC illustrate a method for manufacturing the memory device including an SGT according to the first embodiment;

FIGS. 5BA, 5BB, and 5BC illustrate the method for manufacturing the memory device including an SGT according to the first embodiment;

FIGS. 5CA, 5CB, and 5CC illustrate the method for manufacturing the memory device including an SGT according to the first embodiment;

FIGS. 5DA, 5DB, and 5DC illustrate the method for manufacturing the memory device including an SGT according to the first embodiment;

FIGS. 5EA, 5EB, and 5EC illustrate the method for manufacturing the memory device including an SGT according to the first embodiment;

FIGS. 5FA, 5FB, 5FC, and 5FD illustrate the method for manufacturing the memory device including an SGT according to the first embodiment;

FIGS. 5GA, 5GB, 5GC, and 5GD illustrate the method for manufacturing the memory device including an SGT according to the first embodiment;

FIGS. 5HA, 5HB, and 5HC illustrate the method for manufacturing the memory device including an SGT according to the first embodiment;

FIG. 5I illustrates the method for manufacturing the memory device including an SGT according to the first embodiment;

FIGS. 6AA, 6AB, and 6AC illustrate a method for manufacturing a memory device including an SGT according to a second embodiment;

FIGS. 6BA, 6BB, and 6BC illustrate the method for manufacturing the memory device including an SGT according to the second embodiment;

FIGS. 6CA, 6CB, and 6CC illustrate the method for manufacturing the memory device including an SGT according to the second embodiment;

FIGS. 6DA, 6DB, and 6DC illustrate the method for manufacturing the memory device including an SGT according to the second embodiment;

FIGS. 6EA, 6EB, and 6EC illustrate the method for manufacturing the memory device including an SGT according to the second embodiment;

FIG. 6F illustrates the method for manufacturing the memory device including an SGT according to the second embodiment;

FIGS. 7A, 7B, 7C, and 7D illustrate a problem with the operation of an example of a capacitorless DRAM memory cell in the related art;

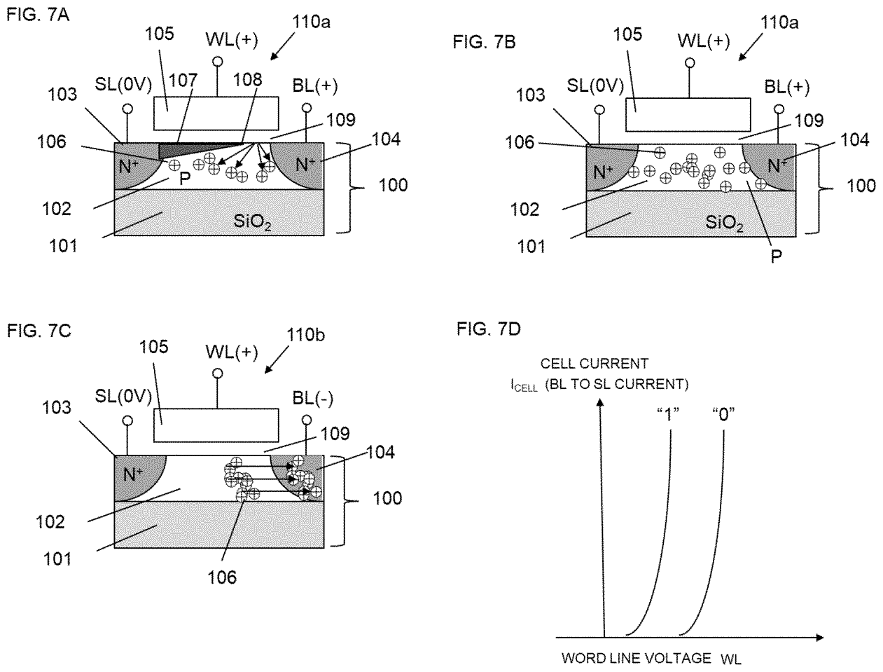

FIGS. 8A and 8B illustrate the problem with the operation of the capacitorless DRAM memory cell in the related art; and

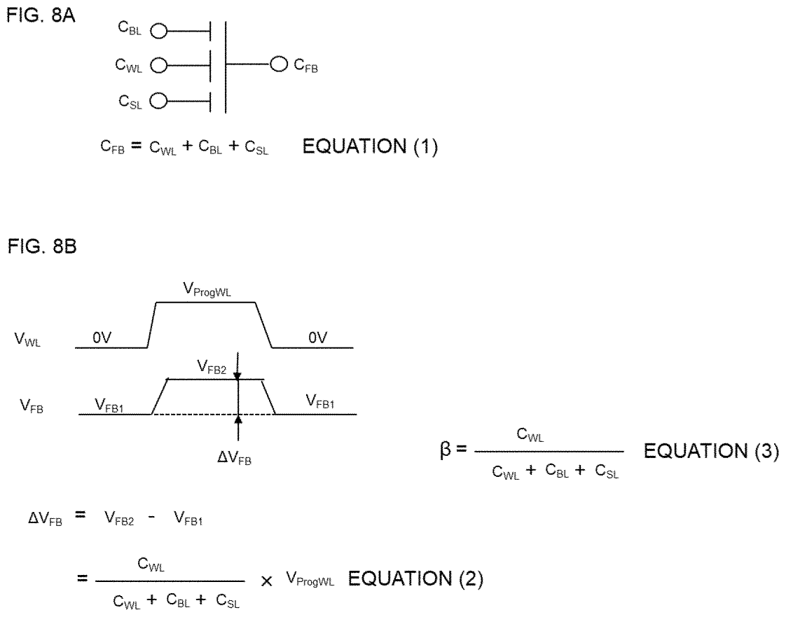

FIGS. 9A, 9B, and 9C illustrate the read operation of the capacitorless DRAM memory cell in the related art.

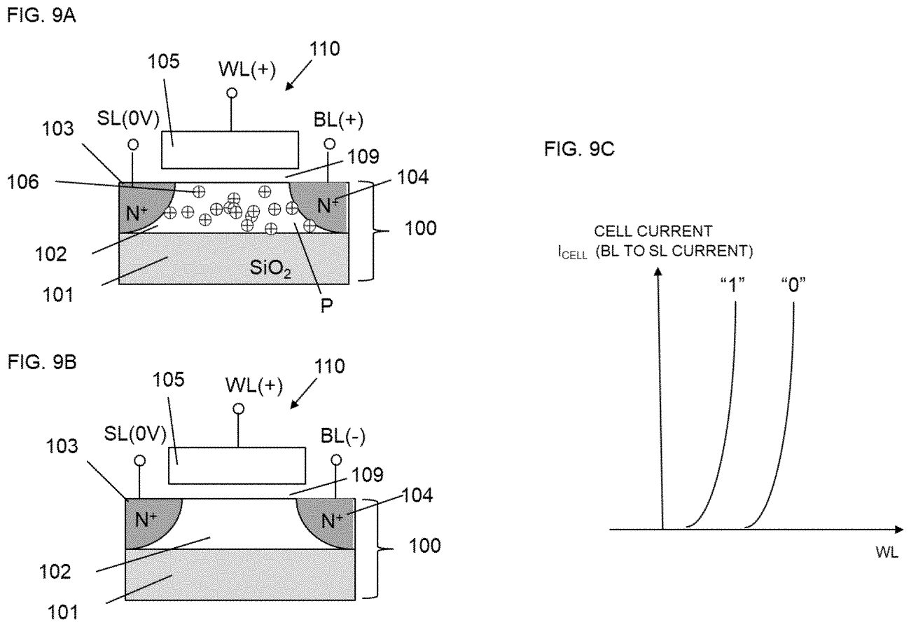

### DESCRIPTION OF THE PREFERRED EMBODIMENTS

Memory devices including semiconductor elements (hereinafter referred to as “dynamic flash memory”) and methods for manufacturing the memory devices according to embodiments of the present invention will be described below with reference to the drawings.

### First Embodiment

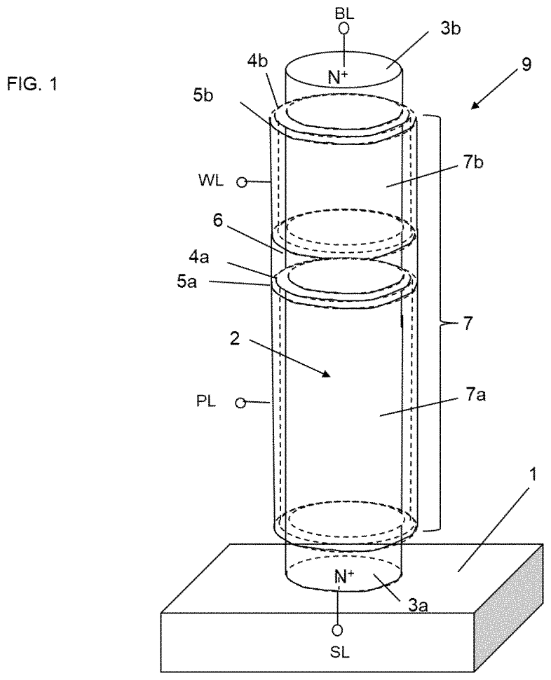

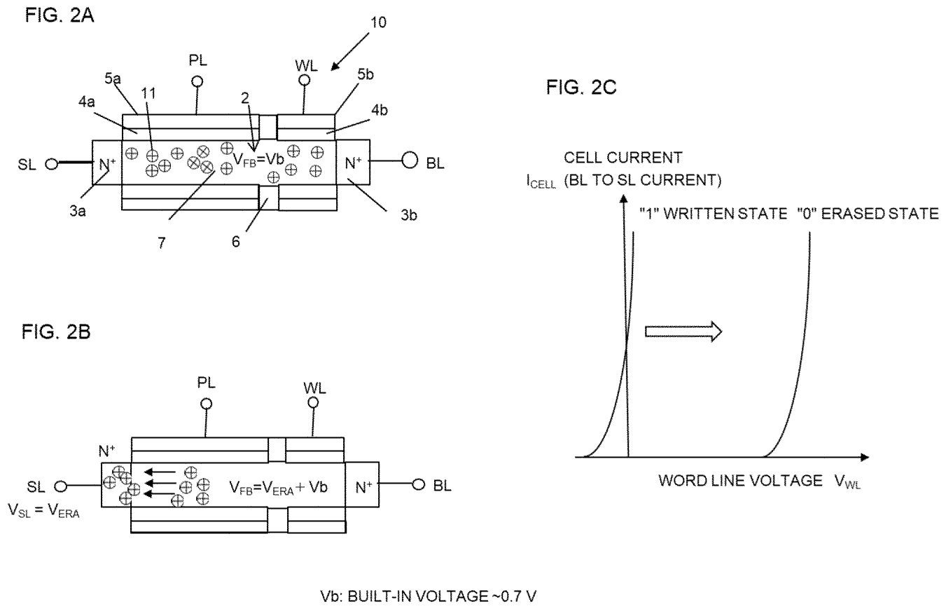

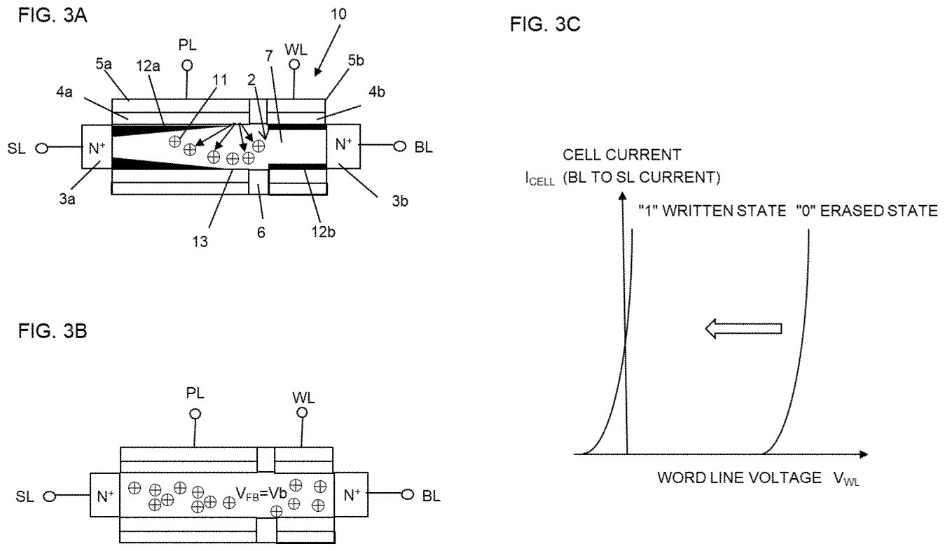

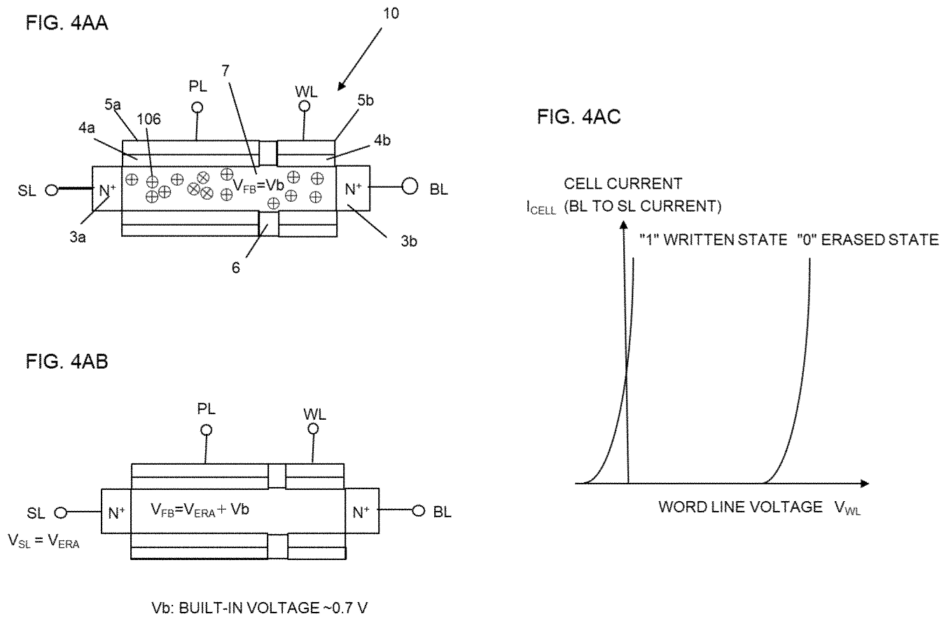

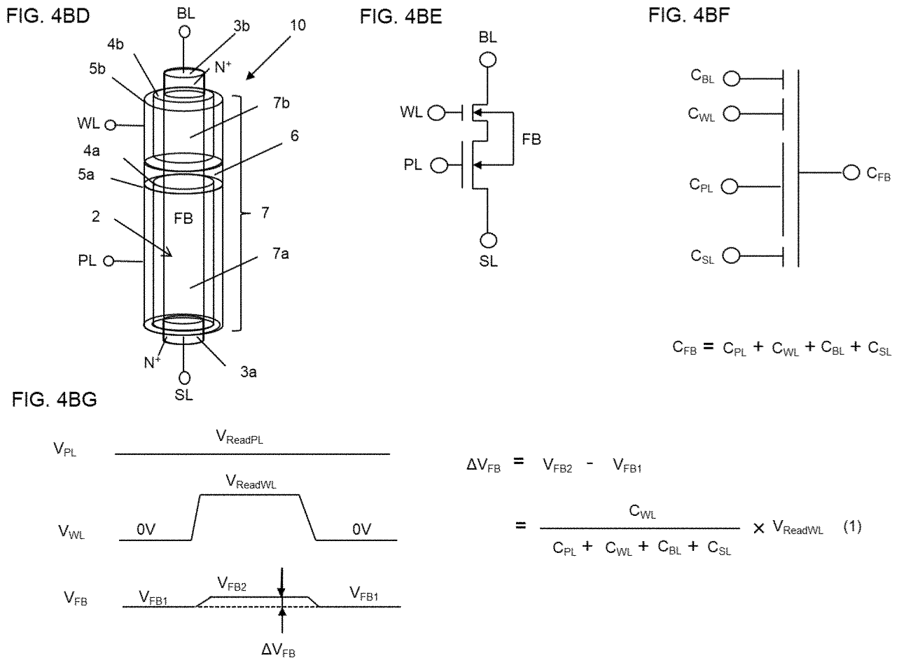

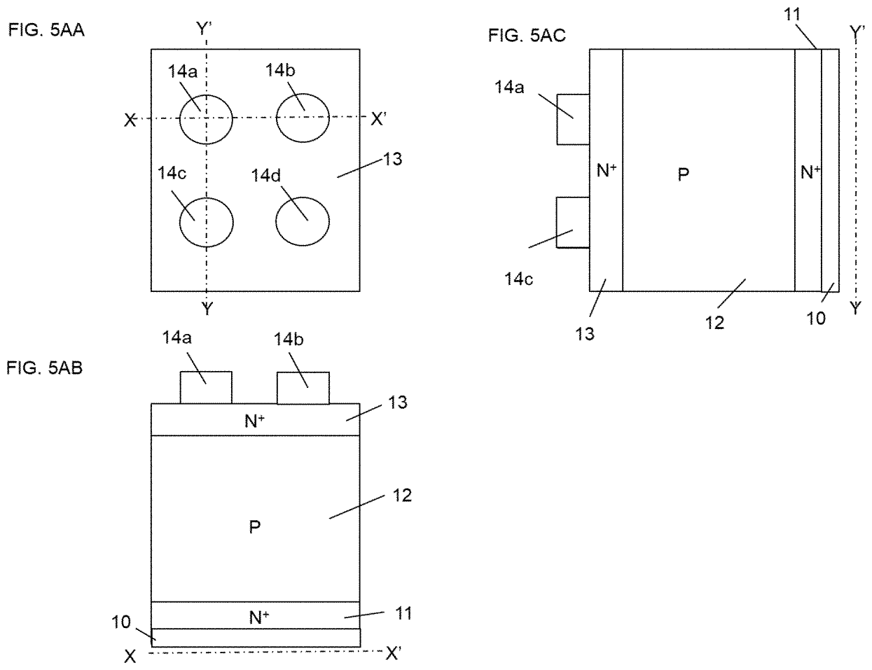

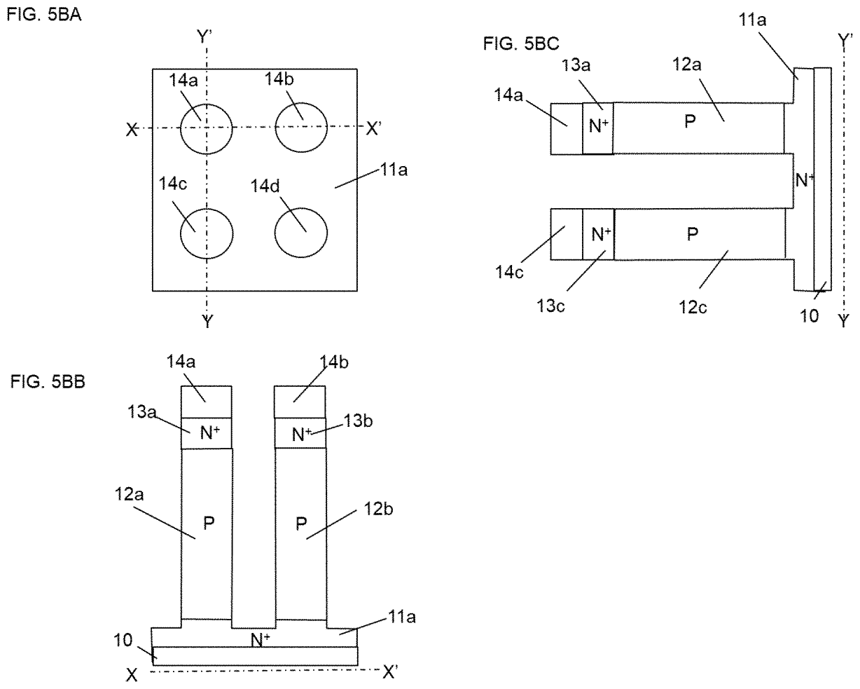

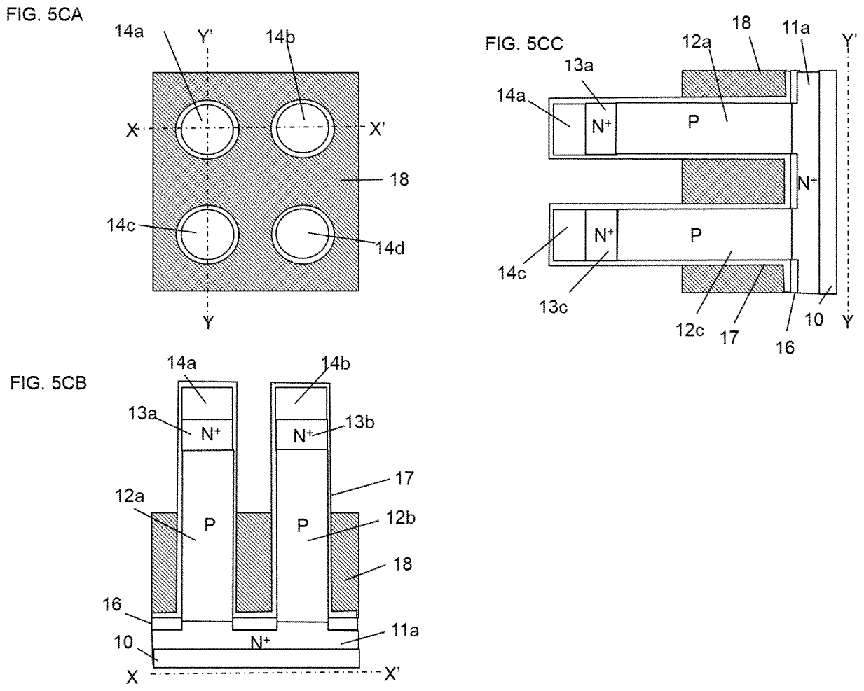

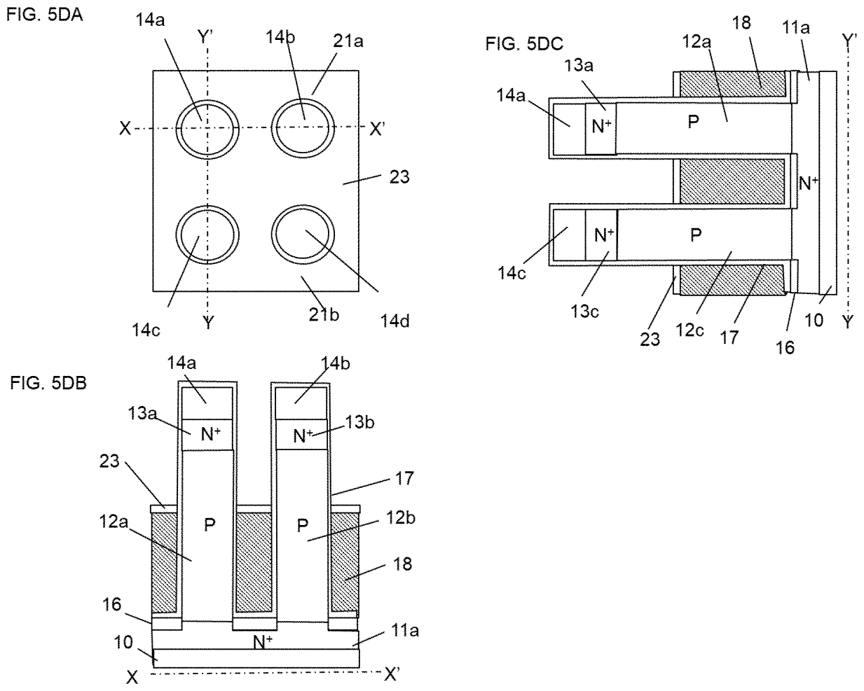

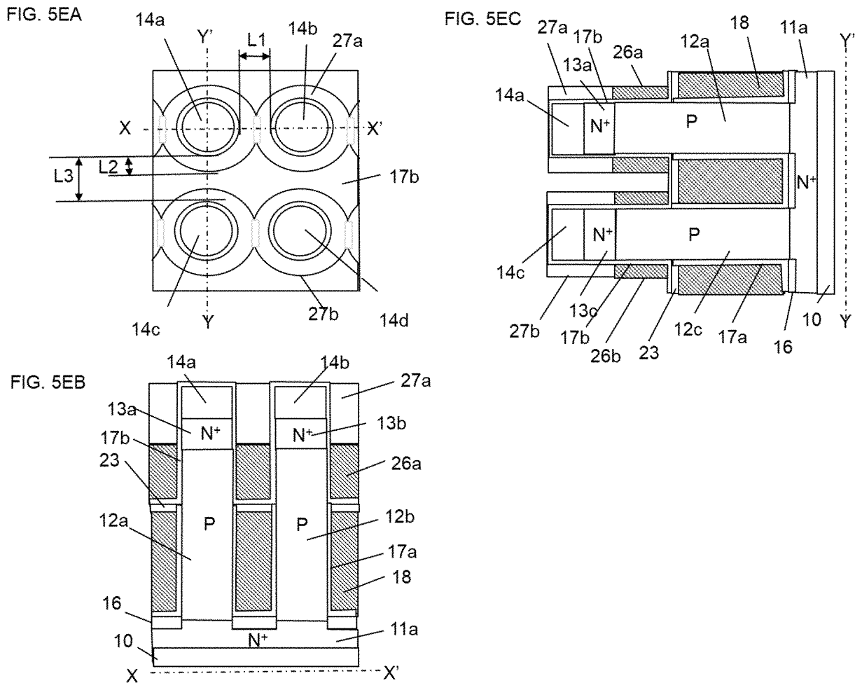

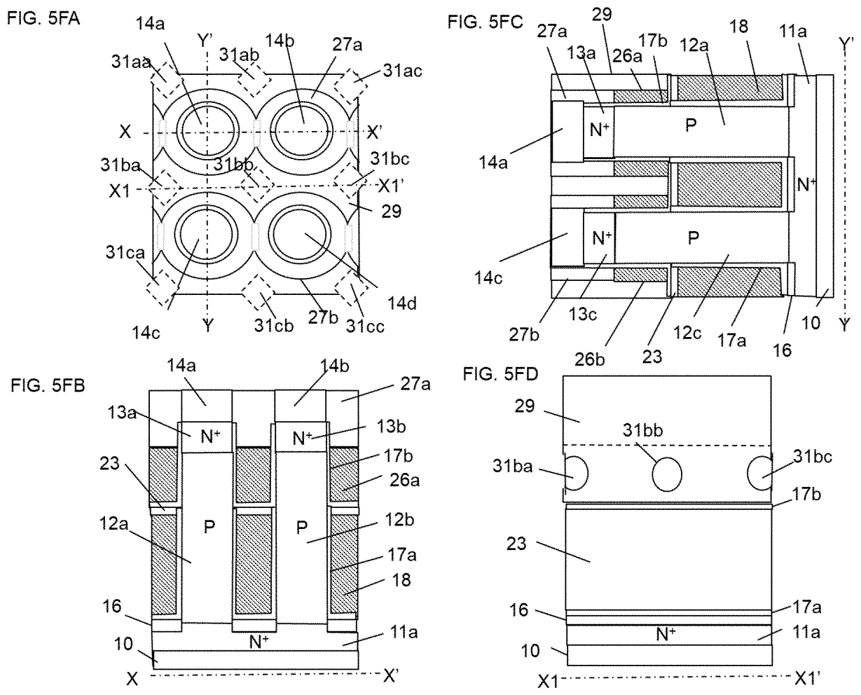

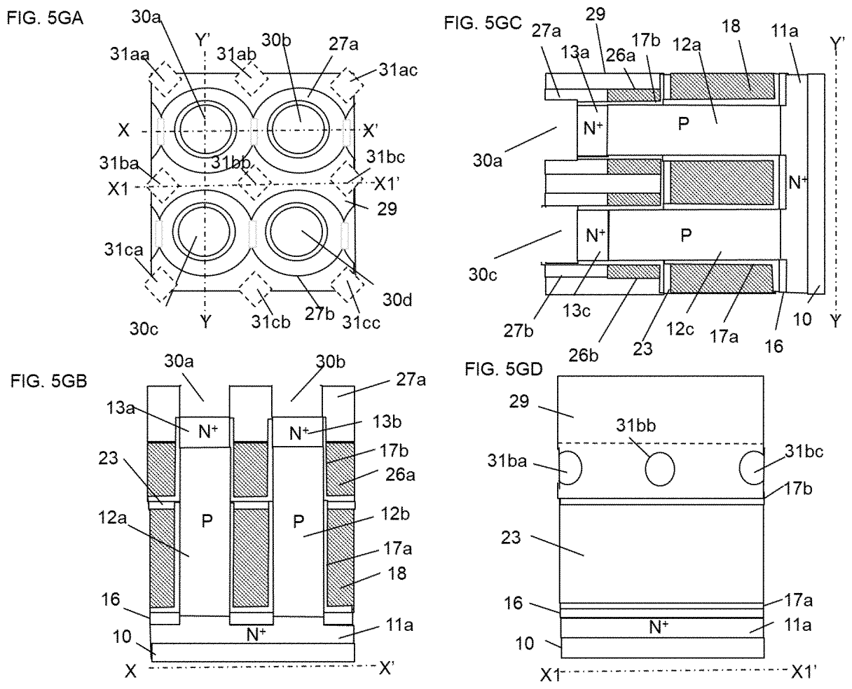

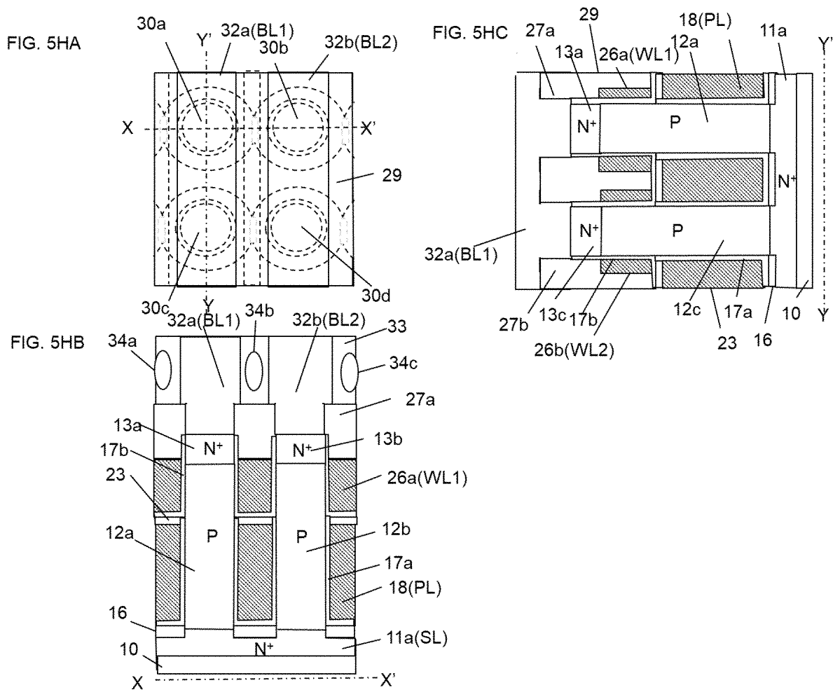

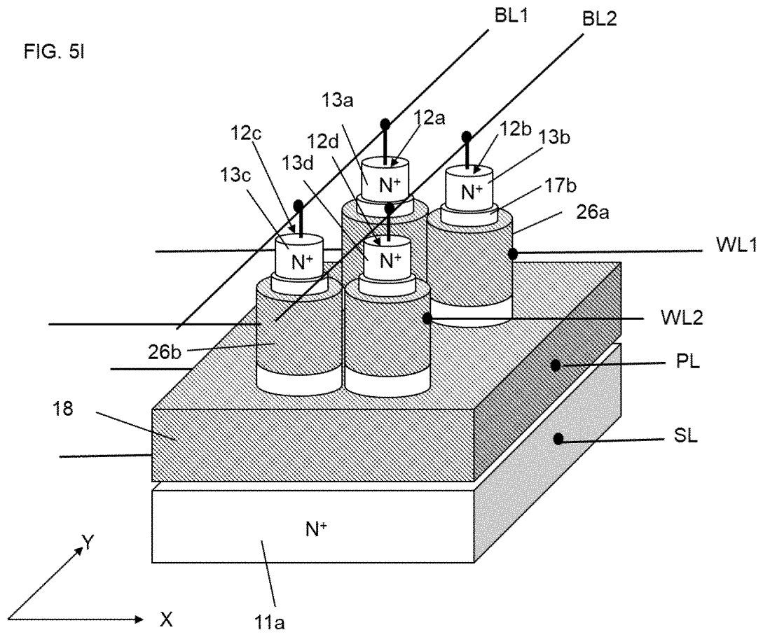

The structure, operating mechanism, and method of manufacture of a dynamic flash memory cell according to a first embodiment of the present invention will be described with reference to FIGS. 1 to 5I. The structure of the dynamic flash memory cell will be described with reference to FIG. 1. The data erase mechanism will be described with reference to FIGS. 2A to 2C. The data write mechanism will be described with reference to FIGS. 3A to 3C. The data read mechanism will be described with reference to FIGS. 4AA to 4BG. The method for manufacturing the dynamic flash memory will be described with reference to FIGS. 5AA to 5I.

FIG. 1 illustrates the structure of the dynamic flash memory cell according to the first embodiment of the present invention. N⁺ layers 3a and 3b, one of which serves as a source when the other serves as a drain, are formed at upper and lower positions within a silicon semiconductor pillar 2 (a silicon semiconductor pillar is hereinafter referred to as “Si pillar”) of P-type or i-type (intrinsic type) conductivity formed on a substrate 1. The portion of the Si pillar 2 between the N⁺ layers 3a and 3b serving as the source and the drain serves as a channel region 7. A gate insulating layer including a first gate insulating layer 4a and a second gate insulating layer 4b is formed so as to surround the channel region 7. The first gate insulating layer 4a and the second gate insulating layer 4b are in contact with or in proximity to the N⁺ layers 3a and 3b, respectively, serving as the source and the drain. A first gate conductor layer 5a and a second gate conductor layer 5b are formed so as to surround the first gate insulating layer 4a and the second gate insulating layer 4b, respectively. The first gate conductor layer 5a and the second gate conductor layer 5b are isolated from each other by an insulating layer 6. The channel region 7, which is the portion of the Si pillar 2 between the N⁺ layers 3a and 3b, includes a first channel region 7a surrounded by the first gate insulating layer 4a and a second channel region 7b surrounded by the second gate insulating layer 4b. Thus, a dynamic flash memory cell 9 including the N⁺ layers 3a and 3b serving as the source and the drain, the channel region 7, the first gate insulating layer 4a, the second gate insulating layer 4b, the first gate conductor layer 5a, and the second gate conductor layer 5b is formed. The N⁺ layer 3a serving as the source is connected to a source line SL. The N⁺ layer 3b serving as the drain is connected to a bit line BL. The first gate conductor layer 5a is connected to a plate line PL. The second gate conductor layer 5b is connected to a word line WL. It is desirable to have a structure in which the gate capacitance of the first gate conductor layer 5a having the plate line PL connected thereto is greater than the gate capacitance of the second gate conductor layer 5b having the word line WL connected thereto. The first gate insulating layer 4a and the second gate insulating layer 4b may be formed as a single continuous insulating layer or may be separately formed.

In FIG. 1, the gate length of the first gate conductor layer 5a is longer than the gate length of the second gate conductor layer 5b so that the gate capacitance of the first gate conductor layer 5a having the plate line PL connected thereto is greater than the gate capacitance of the second gate conductor layer 5b having the word line WL connected thereto. However, the gate length of the first gate conductor layer 5a need not be longer than the gate length of the second gate conductor layer 5b; instead, the thicknesses of the gate insulating layers 4a and 4b may be varied so that the thickness of the gate insulating film forming the first gate insulating layer 4a is smaller than the thickness of the gate insulating film forming the second gate insulating layer 4b. Alternatively, the dielectric constants of the materials for the gate insulating layers 4a and 4b may be varied so that the dielectric constant of the gate insulating film forming the first gate insulating layer 4a is higher than the dielectric constant of the gate insulating film forming the second gate insulating layer 4b. Any combination of the lengths of the gate conductor layers 5a and 5b, the thicknesses of the gate insulating layers 4a and 4b, and the dielectric constants of the gate insulating layers 4a and 4b may be varied so that the gate capacitance of the first gate conductor layer 5a having the plate line PL connected thereto is greater than the gate capacitance of the second gate conductor layer 5b having the word line WL connected thereto.

The data erase operation mechanism will be described with reference to FIGS. 2A to 2C. The channel region 7 between the N⁺ layers 3a and 3b is electrically isolated from the substrate 1, thus forming a floating body. FIG. 2A illustrates a state in which a group of holes 11 generated by impact ionization in the previous cycle are accumulated in the channel region 7 before the erase operation. As illustrated in FIG. 2B, during the data erase operation, the voltage of the source line SL is set to a negative voltage V_{ERA}. Here, V_{ERA} is, for example, −3 V. As a result, irrespective of the initial potential of the channel region 7, the PN junction between the N⁺ layer 3a serving as the source and having the source line SL connected thereto and the channel region 7 is forward-biased. As a result, the group of holes 11 generated by impact ionization in the previous cycle and accumulated in the channel region 7 are absorbed into the N⁺ layer 3a serving as the source portion, and the potential V_{FB} of the channel region 7 is V_{FB}=V_{ERA}+Vb. Here, Vb is the built-in voltage of the PN junction and is about 0.7 V. Hence, when V_{ERA}=−3 V, the potential of the channel region 7 is −2.3 V. This value represents the potential state of the channel region 7 in the erased state. Thus, when the potential of the channel region 7 of the floating body is a negative voltage, the threshold voltage of the N-channel MOS transistor of the dynamic flash memory cell 10 becomes higher under a substrate bias effect. Accordingly, as illustrated in FIG. 2C, the threshold voltage of the second gate conductor layer 5b having the word line WL connected thereto becomes higher. The erased state of the channel region 7 is logic storage data “0”. By setting the voltage applied to the first gate conductor layer 5a connected to the plate line PL to higher than the threshold voltage for logic storage data “1” and lower than the threshold voltage for logic storage data “0” during data reading, the property of not allowing a current to flow when the voltage of the word line WL is increased during reading of logic storage data “0” can be achieved. This leads to a broader margin of operation. The above conditions for the voltages applied to the bit line BL, the source line SL, the word line WL, and the plate line PL are example conditions for performing the data erase operation and may be other operational conditions where the data erase operation can be performed. For example, the erase operation may be performed with a voltage difference between the bit line BL and the source line SL.

FIGS. 3A to 3C illustrate the data write operation of the dynamic flash memory cell according to the first embodiment of the present invention. As illustrated in FIG. 3A, a voltage of, for example, 0 V is input to the N⁺ layer 3a having the source line SL connected thereto, a voltage of, for example, 3 V is input to the N⁺ layer 3b having the bit line BL connected thereto, a voltage of, for example, 2 V is input to the first gate conductor layer 5a having the plate line PL connected thereto, and a voltage of, for example, 5 V is input to the second gate conductor layer 5b having the word line WL connected thereto. As a result, as illustrated in FIG. 3A, an annular inversion layer 12a is formed inside the first gate conductor layer 5a having the plate line PL connected thereto, and a first N-channel MOS transistor region formed by the portion of the channel region 7 surrounded by the first gate conductor layer 5a is operated in the saturation region. As a result, a pinch-off point 13 is present in the inversion layer 12a inside the first gate conductor layer 5a having the plate line PL connected thereto. On the other hand, a second N-channel MOS transistor region formed by the portion of the channel region 7 surrounded by the second gate conductor layer 5b having the word line WL connected thereto is operated in the linear region. As a result, an inversion layer 12b is formed without a pinch-off point over the entire surface inside the second gate conductor layer 5b having the word line WL connected thereto. The inversion layer 12b formed over the entire surface inside the second gate conductor layer 5b having the word line WL connected thereto functions as a virtual drain of the second N-channel MOS transistor region formed by the portion of the channel region 7 surrounded by the second gate conductor layer 5b. As a result, the maximum electric field is reached in a boundary region (first boundary region) in the channel region 7 between the first N-channel MOS transistor region having the first gate conductor layer 5a and the second N-channel MOS transistor region having the second gate conductor layer 5b that are series-connected, and an impact ionization phenomenon occurs in this region. Because this region is a region on the source side as viewed from the second N-channel MOS transistor region having the second gate conductor layer 5b having the word line WL connected thereto, this phenomenon is referred to as source-side impact ionization phenomenon. This source-side impact ionization phenomenon causes electrons to flow from the N⁺ layer 3a having the source line SL connected thereto toward the N⁺ layer 3b having the bit line BL connected thereto. The accelerated electrons collide with the lattice Si atoms, and electron-hole pairs are generated by their kinetic energy. While some of the generated electrons flow into the first gate conductor layer 5a and the second gate conductor layer 5b, most of the electrons flow into the N⁺ layer 3b having the bit line BL connected thereto. In “1” writing, a gate-induced drain leakage (GIDL) current may also be used to generate electron-hole pairs and fill the floating body FB with the group of generated holes (see E. Yoshida, and T. Tanaka: “A Capacitorless 1T-DRAM Technology Using Gate-Induced Drain-Leakage (GIDL) Current for Low-Power and High-Speed Embedded Memory,” IEEE Transactions on Electron Devices, Vol. 53, No. 4, pp. 692-697, April 2006).

As illustrated in FIG. 3B, the group of generated holes 11, which are majority carriers in the channel region 7, charge the channel region 7 to a positive bias. Because the N⁺ layer 3a having the source line SL connected thereto is at 0 V, the channel region 7 is charged to the built-in voltage Vb (about 0.7 V) of the PN junction between the N⁺ layer 3a having the source line SL connected thereto and the channel region 7. When the channel region 7 is charged to a positive bias, the threshold voltage of the first N-channel MOS transistor region and the second N-channel MOS transistor region becomes lower under a substrate bias effect. Thus, as illustrated in FIG. 3C, the threshold voltage of the N-channel MOS transistor of the second channel region 7b having the word line WL connected thereto becomes lower. This written state of the channel region 7 is assigned to logic storage data “1”.

During the write operation, electron-hole pairs may be generated by an impact ionization phenomenon or a GIDL current in a second boundary region between the N⁺ layer 3a and the first channel region 7a or in a third boundary region between the N⁺ layer 3b and the second channel region 7b, rather than in the first boundary region, and the channel region 7 may be charged with the group of generated holes 11. The above conditions for the voltages applied to the bit line BL, the source line SL, the word line WL, and the plate line PL are example conditions for performing the write operation and may be other operational conditions where the write operation can be performed.

The read operation of the dynamic flash memory cell according to the first embodiment of the present invention and the related memory cell structure will be described with reference to FIG. 4AA to 4BG. The read operation of the dynamic flash memory cell will be described with reference to FIGS. 4AA to 4AC. As illustrated in FIG. 4AA, when the channel region 7 is charged to the built-in voltage Vb (about 0.7 V), the threshold voltage of the N-channel MOS transistor decreases under a substrate bias effect. This state is assigned to logic storage data “1”. As illustrated in FIG. 4AB, when the memory block selected before writing is in the erased state “0” in advance, the floating voltage V_{FB} of the channel region 7 is V_{ERA}+Vb. The written state “1” is randomly stored by the write operation. As a result, logic storage data representing logic “0” and logic “1” is created for the word line WL. As illustrated in FIG. 4AC, reading is performed by a sense amplifier using the difference between the two threshold voltages for the word line WL. By setting the voltage applied to the first gate conductor layer 5a connected to the plate line PL to higher than the threshold voltage for logic storage data “1” and lower than the threshold voltage for logic storage data “0” during data reading, the property of not allowing a current to flow when the voltage of the word line WL is increased during reading of logic storage data “0” can be achieved. This leads to a broader margin of operation.

The magnitude relationship between the gate capacitances of the first gate conductor layer 5a and the second gate conductor layer 5b and the related operation during the read operation of the dynamic flash memory cell according to the first embodiment of the present invention will be described with reference to FIGS. 4BD to 4BG. It is desirable that the gate capacitance of the second gate conductor layer 5b having the word line WL connected thereto be lower than the gate capacitance of the first gate conductor layer 5a having the plate line PL connected thereto. As illustrated in FIG. 4BD, the length of the first gate conductor layer 5a having the plate line PL connected thereto in the perpendicular direction is longer than the length of the second gate conductor layer 5b having the word line WL connected thereto in the perpendicular direction so that the gate capacitance of the second gate conductor layer 5b having the word line WL connected thereto is smaller than the gate capacitance of the first gate conductor layer 5a having the plate line PL connected thereto. FIG. 4BE illustrates an equivalent circuit of one cell of the dynamic flash memory in FIG. 4BD. FIG. 4BF illustrates the coupling capacitance relationship of the dynamic flash memory. Here, C_{WL} is the capacitance of the second gate conductor layer 5b, C_{PL} is the capacitance of the first gate conductor layer 5a, C_{BL} is the capacitance of the PN junction between the N⁺ layer 3b serving as the drain and the second channel region 7b, and C_{SL} is the capacitance of the PN junction between the N⁺ layer 3a serving as the source and the first channel region 7a. As illustrated in FIG. 4BG, as the voltage of the word line WL oscillates, its operation affects the channel region 7 as noise. The potential variation ΔV_{FB} in the channel region 7 in this case is ΔV_{FB}=C_{WL}/(C_{PL}+C_{WL}+C_{BL}+C_{SL})×V_{ReadWL}. Here, V_{ReadWL} iS the oscillation potential of the word line WL during reading. As is obvious from equation (1), it can be understood that ΔV_{FB} becomes smaller as the contribution ratio of C_{WL} becomes smaller relative to the total capacitance of the channel region 7, i.e., C_{PL}+C_{WL}+C_{BL}+C_{SL}. To increase C_{BL}+C_{SL}, which is the capacitance of the PN junctions, for example, the diameter of the Si pillar 2 may be increased. This, however, is undesirable for miniaturization of memory cells. In contrast, if the length of the first gate conductor layer 5a having the plate line PL connected thereto in the perpendicular direction is longer than the length of the second gate conductor layer 5b having the word line WL connected thereto in the perpendicular direction, ΔV_{FB} can be further reduced without decreasing the degree of integration of memory cells in plan view. Data reading may also be performed by bipolar operation. The above conditions for the voltages applied to the bit line BL, the source line SL, the word line WL, and the plate line PL are example conditions for performing the read operation and may be other operational conditions where the read operation can be performed.

A method for manufacturing the dynamic flash memory according to this embodiment will be described with reference to FIGS. 5AA to 5I. FIGS. 5AA, 5BA, 5CA, 5DA, 5EA, 5FA, 5GA, and 5HA illustrate plan views. FIGS. 5AB, 5BB, 5CB, 5DB, 5EB, 5FB, 5GB, and 5HB illustrate sectional views taken along lines X-X′ of FIGS. 5AA, 5BA, 5CA, 5DA, 5EA, 5FA, 5GA, and 5HA. FIGS. 5AC, 5BC, 5CC, 5DC, 5EC, 5FC, 5GC, and 5HC illustrate sectional views taken along lines Y-Y′ of FIGS. 5AA, 5BA, 5CA, 5DA, 5EA, 5FA, 5GA, and 5HA.

As illustrated in FIGS. 5AA to 5AC, in order from bottom, an N⁺ layer 11 (an example of “first impurity region” in the claims), a P layer 12 formed of Si, and an N⁺ layer 13 are formed over a substrate 10 (an example of “substrate” in the claims). Mask material layers 14a, 14b, 14c, and 14d that are circular in plan view are then formed. The substrate 10 may be a silicon-on-insulator (SOI) substrate or a single layer or a plurality of layers of Si or another semiconductor material. The substrate 10 may also be an N or P well layer composed of a single layer or a plurality of layers.

Next, as illustrated in FIGS. 5BA to 5BC, the N⁺ layer 13, the P layer 12, and the upper portion of the N⁺ layer 11 are etched using the mask material layers 14a to 14d as a mask to form, over an N⁺ layer 11a, a Si pillar 12a (an example of “first semiconductor pillar” in the claims), a Si pillar 12b (an example of “second semiconductor pillar” in the claims), a Si pillar 12c (an example of “third semiconductor pillar” in the claims), a Si pillar 12d (not illustrated; an example of “fourth semiconductor pillar” in the claims), and N⁺ layers 13a, 13b, 13c, and 13d (not illustrated) (each of which is an example of “second impurity region” in the claims).

Next, as illustrated in FIGS. 5CA to 5CC, a HfO₂ layer 17 serving as a gate insulating layer is formed over the entire surface, for example, by atomic layer deposition (ALD). A TiN layer (not illustrated) serving as a gate conductor layer is then formed over the entire surface. The TIN layer is then polished by chemical mechanical polishing (CMP) such that the upper surface thereof is located at the upper surfaces of the mask material layers 14a to 14d. The TiN layer is then etched by reactive ion etching (RIE) such that the upper surface thereof is located near the midpoints of the Si pillars 12a to 12d in the perpendicular direction to form a TiN layer 18 (an example of “first gate conductor layer” in the claims). The HfO₂ layer 17 may be replaced by another insulating layer composed of a single layer or a plurality of layers as long as the insulating layer functions as a gate insulating layer. The TiN layer 18 may also be replaced by another conductor layer composed of a single layer or a plurality of layers as long as the conductor layer functions as a gate conductor layer. In addition, it is desirable to etch the TiN layer such that the upper surface thereof is located above the midpoints of the Si pillars 12a to 12d in the perpendicular direction.

Next, as illustrated in FIGS. 5DA to 5DC, a SiO₂ layer 23 is formed on the TiN layer 18.

Next, as illustrated in FIGS. 5EA to 5EC, the portion of the HfO₂ layer 17 above the SiO₂ layer 23 is etched to form a HfO₂ layer 17a (an example of “gate insulating layer” in the claims). A HfO₂ layer 17b (an example of “gate insulating layer” in the claims) is then formed over the entire surface. A TiN layer (not illustrated) is then formed over the entire surface by a chemical vapor deposition (CVD) process. The TiN layer is polished by a CMP process and is then etched by an RIE process such that the upper surface thereof is located near the lower ends of the N⁺ layers 13a to 13d. A SiN layer 27a is then formed so as to surround and extend between the side surfaces of the N⁺ layers 13a and 13b and the mask material layers 14a and 14b. Similarly, a SiN layer 27b is formed so as to surround and extend between the side surfaces of the N⁺ layers 13c and 13d and the mask material layers 14c and 14d. The TiN layer is then etched using the SiN layers 27a and 27b as a mask to form a TiN layer 26a (an example of “second gate conductor layer” in the claims) and a TiN layer 26b (an example of “third gate conductor layer” in the claims). Here, because the length L1 (an example of “first length” in the claims) between the points of intersection of the outer periphery lines of the HfO₂ layer 17b surrounding the Si pillars 12a and 12b and line X-X′ is smaller than twice the width L2 of the SiN layers 27a and 27b on line Y-Y′, and the length L3 between the points of intersection of the outer periphery lines of the HfO₂ layer 17b surrounding the Si pillars 12a and 12c and line Y-Y′ is greater than twice L2, the SiN layer 27a can be formed so as to extend between the Si pillars 12a and 12b and to be separated from the SiN layer 27b between the Si pillars 12a and 12c. Similarly, the SiN layer 27b is formed so as to extend between the Si pillars 12c and 12d and to be separated from the SiN layer 27a between the Si pillars 12b and 12d.

Next, as illustrated in FIGS. 5FA to 5FD, a SiO₂ layer 29 including voids 31aa, 31ab, 31ac, 31ba, 31bb, 31bc, 31ca, 31cb, and 31cc (an example of “first void” in the claims) is formed between and around the side surfaces of the TiN layers 26a and 26b and the SiN layers 27a and 27b. The voids 31aa, 31ab, 31ac, 31ba, 31bb, 31bc, 31ca, 31cb, and 31cc are formed such that the upper ends thereof are located below the upper ends of the TiN layers 26a and 26b, as indicated by the dotted line in FIG. 5FD (a sectional view taken along line X1-X1′ of FIG. 5FA; this also applies to FIG. 5GD).

Next, as illustrated in FIGS. 5GA to 5GD, the mask material layers 14a to 14d are etched to form contact holes 30a, 30b, 30c, and 30d.

Next, as illustrated in FIGS. 5HA to 5HC, a bit line BL1 conductor layer 32a (an example of “first wiring conductor layer” in the claims) connected to the N⁺ layers 13a and 13c through the contact holes 30a and 30c and a bit line BL2 conductor layer 32b (an example of “second wiring conductor layer” in the claims) connected to the N⁺ layers 13b and 13d through the contact holes 30b and 30d are formed. A SiO₂ layer 33 including voids 34a, 34b, and 34c (an example of “second void” in the claims) is then formed between and on both sides of the bit line BL1 conductor layer 32a and the bit line BL2 conductor layer 32b. Thus, a dynamic flash memory is formed on the substrate 10. The TiN layers 26a and 26b serve as word line conductor layers WL1 and WL2, the TiN layer 18 serves as a plate line conductor layer PL that also serves as a gate conductor layer, and the N⁺ layer 11a serves as a source line conductor layer SL that also serves as a source impurity layer.

FIG. 51 illustrates a schematic structural view of the dynamic flash memory illustrated in FIGS. 5HA to 5HC. The N⁺ layer 11a serving as the source line conductor layer SL is formed so as to extend over the entire surface. The plate line conductor layer PL is also formed so as to extend over the entire surface. The gate conductor TiN layer 26a connected to the word line conductor layer WL1 is formed so as to extend between the adjacent Si pillars 12a and 12b in the X direction. Similarly, the gate conductor TiN layer 26b connected to the word line conductor layer WL2 is formed so as to extend between the adjacent Si pillars 12c and 12d in the X direction. The bit line conductor layer BL1 connected to the N⁺ layers 13a and 13c and the bit line conductor layer BL2 connected to the N⁺ layers 13b and 13d are formed in the Y direction orthogonal to the X direction.

In FIG. 1, the length of the first gate conductor layer 5a having the plate line PL connected thereto in the perpendicular direction is longer than the length of the second gate conductor layer 5b having the word line WL connected thereto in the perpendicular direction, i.e., C_{PL}>C_{WL}. However, the capacitive coupling ratio of the word line WL to the channel region 7 (C_{WL}/(C_{PL}+C_{WL}+C_{BL}+C_{SL})) is reduced simply by adding the plate line PL. As a result, the potential variation ΔV_{FB} in the channel region 7 of the floating body is reduced.

In addition, a fixed voltage of, for example, 2 V may be applied as the voltage V_{ERAsePL} of the plate line PL irrespective of the mode of operation. In addition, a voltage of, for example, 0 V may be applied as the voltage V_{ERAsePL} of the plate line PL only during erase. In addition, a fixed voltage or a time-varying voltage may be applied as the voltage V_{ERAsePL} of the plate line PL as long as the voltage satisfies the conditions where the dynamic flash memory operation can be achieved.

In addition, the dynamic flash memory operation described in this embodiment can also be achieved when the transverse sectional shape of the Si pillar 2 in FIG. 1 is circular, oval, or rectangular. In addition, circular, oval, and rectangular dynamic flash memory cells may coexist on the same chip.

In addition, in FIG. 1, the first gate conductor layer 5a may be connected to the word line WL, and the second gate conductor layer 5b may be connected to the plate line PL. The dynamic flash memory operation described above can also be achieved in this case. The above connections may be made by reversing the order in which the TiN layer 18 and the TiN layers 26a and 26b are formed in FIGS. 5AA to 5I.

In addition, in FIG. 1, the potential distributions of the first channel region 7a and the second channel region 7b are formed so as to be connected together in the portion of the channel region 7 surrounded by the insulating layer 6 in the perpendicular direction. Thus, the first channel region 7a and the second channel region 7b are connected together in the region of the channel region 7 surrounded by the insulating layer 6 in the perpendicular direction.

In addition, in FIG. 1, one or both of the first gate conductor layer 5a and the second gate conductor layer 5b may be split into two segments in plan view. In addition, one or both of the first gate conductor layer 5a and the second gate conductor layer 5b may be split into a plurality of segments in the perpendicular direction. The segments of the split first gate conductor layer 5a or second gate conductor layer 5b may be driven synchronously or asynchronously. This also allows normal memory operation. These also apply to the TiN layers 18, 26a, and 26b in FIGS. 5AA to 5I.

In addition, in FIGS. 5AA to 5I, when the TiN layers 26a and 26b are split into two segments in the perpendicular direction, the lower TiN layer may operate as a plate line, whereas the upper TiN layer may operate as a word line. In this case, the TiN layer 18 may also operate as a second word line. In addition, when the TiN layer 18 is split into two segments in the perpendicular direction, the upper TiN layer may operate as a plate line, whereas the lower TiN layer may operate as a second word line. This also allows normal memory operation. These also apply to the first gate conductor layer 5a and the second gate conductor layer 5b in FIG. 1.

In addition, in FIGS. 5AA to 5I, the Si pillars 12a to 12d are formed by etching the P layer 12 using the mask material layers 14a to 14d as an etching mask. Alternatively, for example, a plurality of material layers may be deposited and etched to form holes, and the Si pillars 12a to 12d may be formed in the holes, for example, by a selective epitaxial crystal growth process.

In FIGS. 5FA to 5FD, the voids 31aa, 31ab, 31ac, 31ba, 31bb, 31bc, 31ca, 31cb, and 31cc are formed so as to be isolated from each other. Alternatively, the distance between the Si pillars 12a and 12c and between the Si pillars 12b and 12d may be increased so that the voids 31aa, 31ab, and 31ac are formed so as to be connected together, the voids 31ba, 31bb, and 31bc are formed so as to be connected together, and the voids 31ca, 31cb, and 31cc are formed so as to be connected together.

This embodiment provides the following features.

### Feature 1

For the dynamic flash memory cell formed in the Si pillar 2 standing on the substrate 1 in the perpendicular direction, as illustrated in FIG. 1, the N⁺ layers 3a and 3b serving as the source and the drain, the channel region 7, the first gate insulating layer 4a, the second gate insulating layer 4b, the first gate conductor layer 5a, and the second gate conductor layer 5b are formed in a pillar shape as a whole. In addition, the N⁺ layer 3a serving as the source is connected to the source line SL, the N⁺ layer 3b serving as the drain is connected to the bit line BL, the first gate conductor layer 5a is connected to the plate line PL, and the second gate conductor layer 5b is connected to the word line WL. The dynamic flash memory cell is characterized by a structure in which the gate capacitance of the first gate conductor layer 5a having the plate line PL connected thereto is greater than the gate capacitance of the second gate conductor layer 5b having the word line WL connected thereto. In this dynamic flash memory cell, the first gate conductor layer 5a and the second gate conductor layer 5b are stacked in the perpendicular direction. Thus, despite having a structure in which the gate capacitance of the first gate conductor layer 5a having the plate line PL connected thereto is greater than the gate capacitance of the second gate conductor layer 5b having the word line WL connected thereto, the memory cell does not have a large area in plan view. This allows a higher performance and a higher degree of integration of dynamic flash memory cells to be simultaneously achieved.

### Feature 2

In the dynamic flash memory cell according to the first embodiment of the present invention, the plate line PL connected to the first gate conductor layer 5a functions to reduce the capacitive coupling ratio of the word line WL to the channel region 7 when the voltage of the word line WL oscillates up and down during the write or read operation of the dynamic flash memory cell. As a result, the effect of variations in the voltage of the channel region 7 that occur when the voltage of the word line WL oscillates up and down can be considerably reduced. Thus, the difference between the SGT transistor threshold voltages of the word line WL that represent logic “0” and logic “1” can be increased. This leads to a broader margin of operation of the dynamic flash memory cell.

### Feature 3

As illustrated in FIG. 51, the TiN layer 18 connected to the plate line PL is formed so as to extend between the Si pillars 12a to 12d in the X and Y directions. This indicates that there is no pattern formed by lithography in the memory cell region. This leads to a lower cost of the mask used and a simpler process.

### Feature 4

As illustrated in 5EA to 5EC, the length L1 between the points of intersection of the outer periphery lines of the HfO₂ layer 17b surrounding the Si pillars 12a and 12b and line X-X′ is smaller than twice the width L2 of the SiN layers 27a and 27b on line Y-Y′, and the length L3 between the points of intersection of the outer periphery lines of the HfO₂ layer 17b surrounding the Si pillars 12a and 12c and line Y-Y′ is greater than twice L2. Thus, the SiN layer 27a can be formed so as to extend between the Si pillars 12a and 12b and to be separated from the SiN layer 27b between the Si pillars 12a and 12c. Similarly, the SiN layer 27b is formed so as to extend between the Si pillars 12c and 12d and to be separated from the SiN layer 27a between the Si pillars 12b and 12d. The SiN layers 27a and 27b are formed in a self-aligned manner with respect to the Si pillars 12a to 12d. Since the TiN layers 26a and 26b are formed using the SiN layers 27 and 27b as an etching mask, the TiN layers 26a and 26b are formed in a self-aligned manner with respect to the Si pillars 12a to 12d. The formation of the TiN layers 26a and 26b in a self-aligned manner leads to a higher degree of integration of a dynamic flash memory. In addition, the TiN layers 26a and 26b are formed without using a mask pattern for a lithography process, which leads to a lower cost of the mask used and a simpler process.

### Feature 5

As illustrated in FIGS. 5GA to 5GD, the contact holes 30a to 30d are formed by removing the mask material layers 14a to 14d used for the formation of the Si pillars 12a to 12d. As illustrated in FIGS. 5HA to 5HC, the N⁺ layers 13a and 13c and the bit line BL1 conductor layer 32a are connected together through the contact holes 30a and 30c. Similarly, the N⁺ layers 13b and 13d and the bit line BL2 conductor layer 32b are connected together through the contact holes 30b and 30d. The contact holes 30a to 30d are formed in a self-aligned manner with respect to the Si pillars 12a to 12d. In addition, there is no need for a lithography process for forming the contact holes 30a to 30d. This allows a high-density dynamic flash memory to be formed at a lower cost.

### Second Embodiment

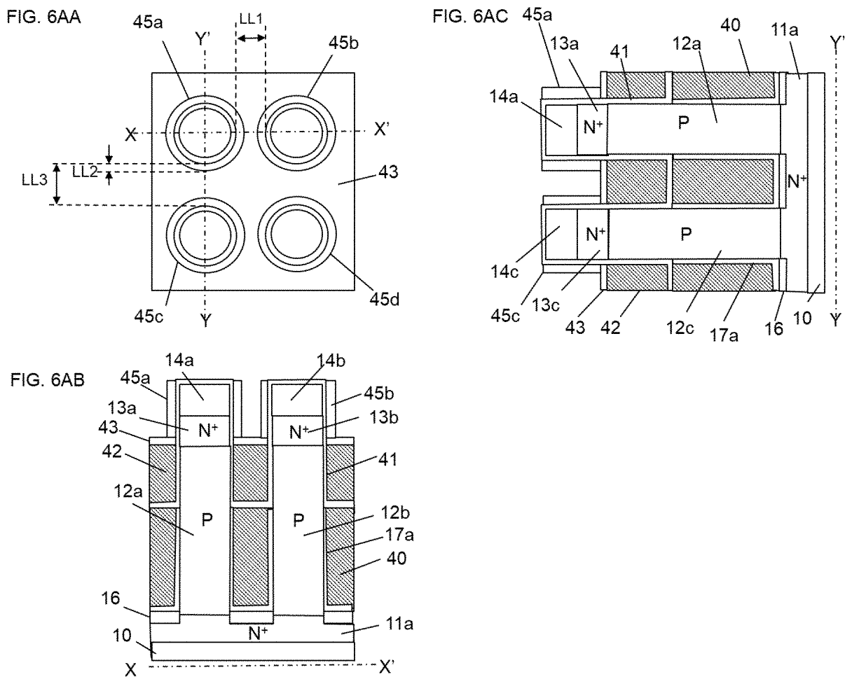

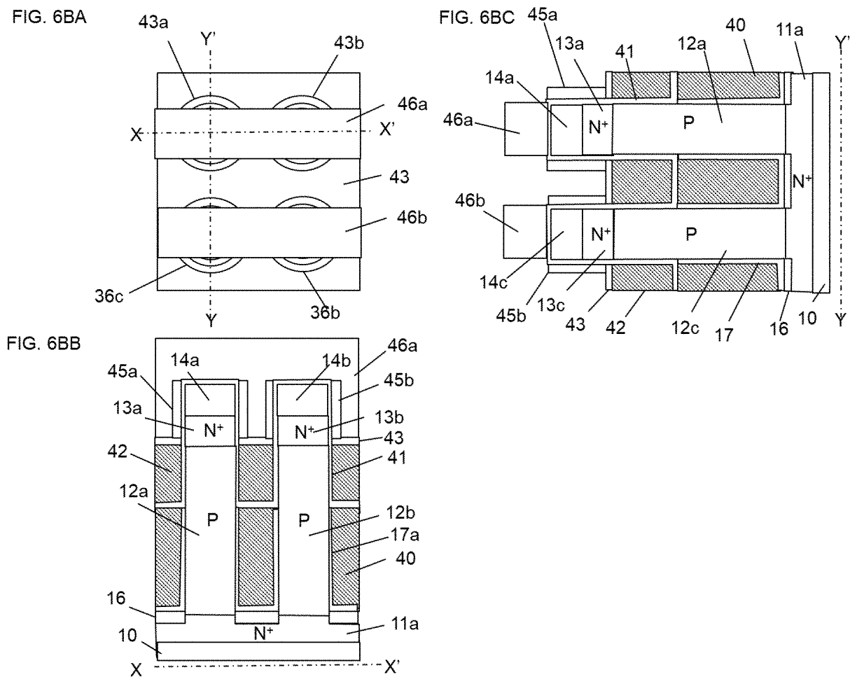

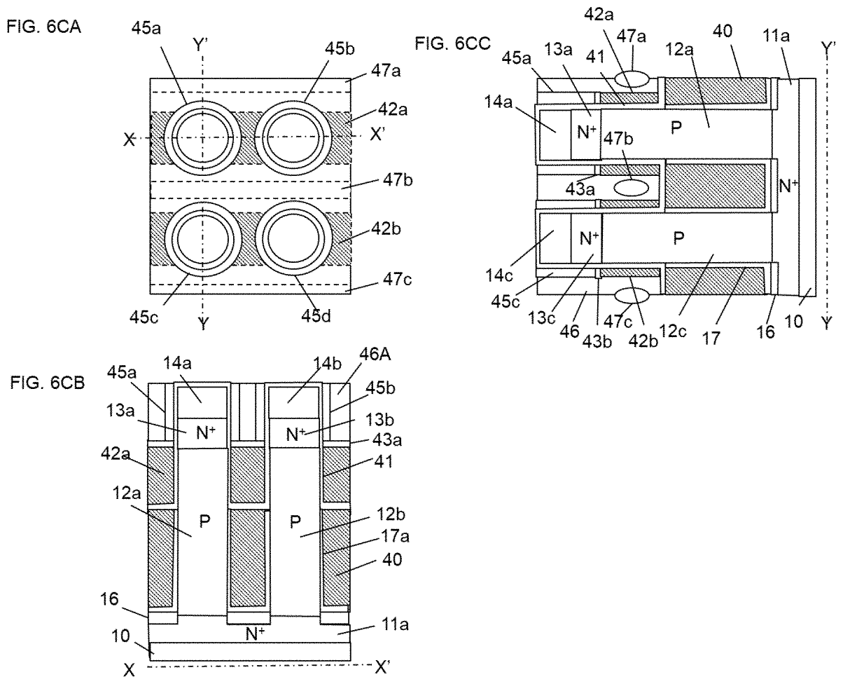

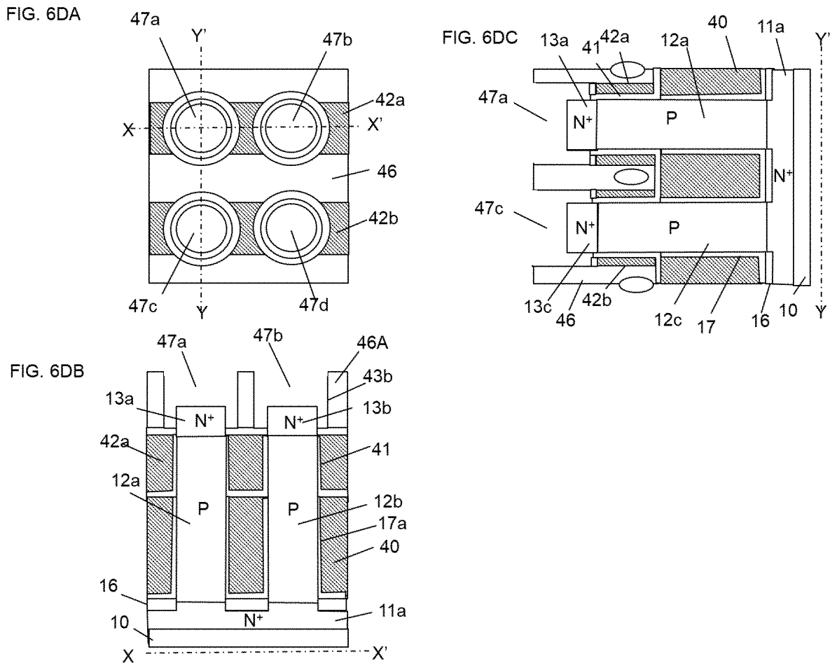

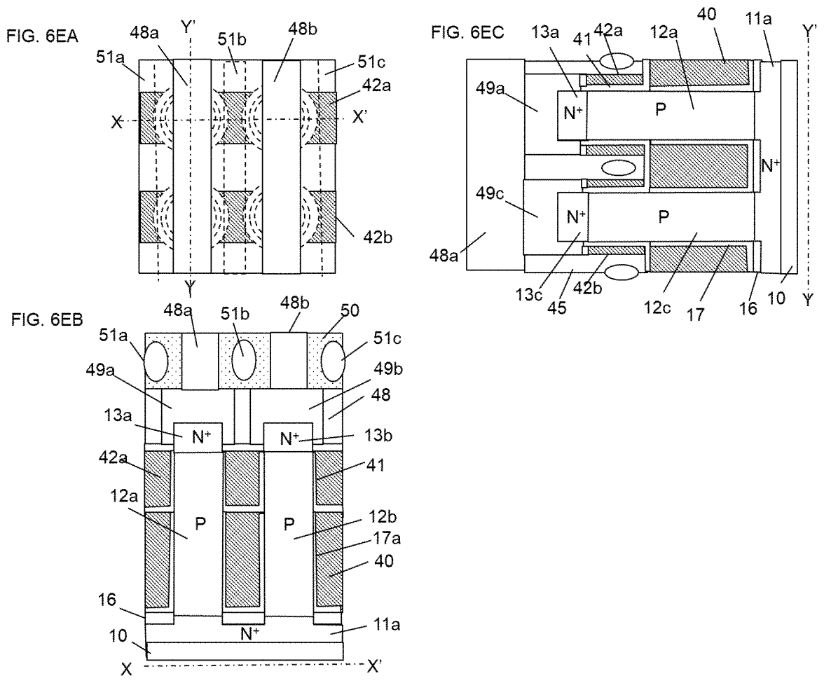

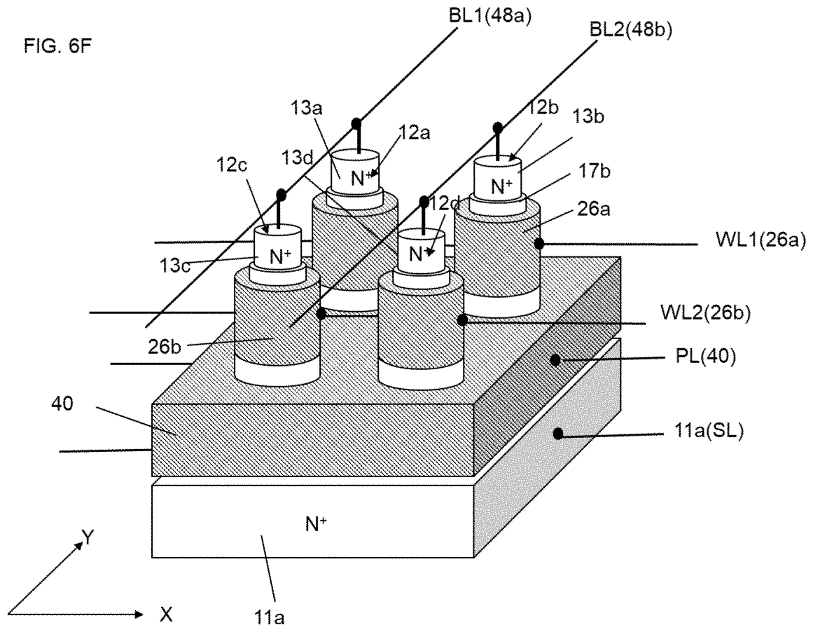

A method for manufacturing a dynamic flash memory according to a second embodiment will be described with reference to FIGS. 6AA to 6EC. FIGS. 6AA, 6BA, 6CA, 6DA, and 6EA illustrate plan views. FIGS. 6AB, 6BB, 6CB, 6DB, and 6EB illustrate sectional views taken along lines X-X′ of FIGS. 6AA, 6BA, 6CA, 6DA, and 6EA. FIGS. 6AC, 6BC, 6CC, 6DC, and 6EC illustrate sectional views taken along lines Y-Y′ of FIGS. 6AA, 6BA, 6CA, 6DA, and 6EA.

The steps illustrated in FIGS. 5AA to 5CC are performed. As illustrated in FIGS. 6AA to 6AC, the portion of the HfO₂ layer 17 above the upper surface of a TiN layer 40 (corresponding to the TiN layer 18 in FIGS. 5DA to 5DC) in the perpendicular direction is then removed to form a HfO₂ layer 17a. A HfO₂ layer 41 is then formed over the entire surface. A TiN layer (not illustrated) is then formed over the entire surface. The TiN layer is then polished by a CMP process such that the upper surface thereof is located at the upper surfaces of the mask material layers 14a to 14d. The TiN layer is then etched by an RIE process such that the upper surface thereof is located near the lower ends of the N⁺ layers 13a to 13d to form a TiN layer 42. An aluminum oxide (AlO) layer 43 is then formed on the TiN layer 42 around the N⁺ layers 13a to 13d. A SiN layer (not illustrated) is then formed over the entire surface. The SiN layer is then polished by a CMP process such that the upper surface thereof is located at the upper surfaces of the mask material layers 14a to 14d. The SiN layer is then etched by an RIE process to form SiN layers 45a, 45b, 45c, and 45d surrounding the HfO₂ layer 41 on the side surfaces of the N⁺ layer 13a to 13d and the mask material layers 14a to 14d. Here, the thickness LL2 of the mask material layers is the thickness of the gate TiN layer on line Y-Y′ in plan view, as described with reference to the subsequent figures. Both the length LL1 between the outer periphery lines of the gate HfO₂ layer 41 surrounding the Si pillars 12a and 12b on line X-X′ and the length LL3 between the outer periphery lines of the gate HfO₂ layer 41 surrounding the Si pillars 12a and 12c on line Y-Y′ are greater than twice the thickness LL2 of the gate TiN layer.

Next, as illustrated in FIGS. 6BA to 6BC, a mask material layer 46a extending in the direction along line X-X′ so as to overlap the Si pillars 12a and 12b in plan view and a mask material layer 46b extending in the direction along line X-X′ so as to overlap the Si pillars 12c and 12d in plan view are formed. Alternatively, the side surfaces of the mask material layers 45a and 45b may be surrounded by, for example, a SiO₂ layer, and the mask material layers 46a and 46b may be formed over the SiO₂ layer and the mask material layers 14a to 14d.

Next, as illustrated in FIGS. 6CA to 6CC, the AlO layer 43 and the TiN layer 42 are etched by an RIE process using the mask material layers 14a to 14d, 45a to 45d, and 46a and 46b as a mask to form AlO layers 43a and 43b and TiN layers 42a and 42b. A SiO₂ layer (not illustrated) is then formed over the entire surface and is polished by a CMP process such that the upper surface thereof is located at the upper surfaces of the mask material layers 14a to 14d to form a SiO₂ layer 46. The SiO₂ layer 46 is formed so as to include voids 47a, 47b, and 47c extending in the direction along line X-X′ in plan view between and on both sides of the TiN layers 42a and 42b. The voids 47a to 47c are formed such that the upper surfaces thereof are located below the upper ends of the TiN layers 42a and 42b. The mask material layer 45a to 45d are formed so as to surround the Si pillars 12a to 12d at equal width in plan view. Thus, in plan view, the TiN layer 42a includes a first region (an example of “first region” in the claims) surrounding the Si pillars 12a and 12b at equal width and a second region extending between the Si pillars 12a and 12b (an example of “second region” in the claims). Similarly, the TiN layer 42b includes a third region (an example of “third region” in the claims) surrounding the Si pillars 12c and 12d at equal width and a fourth region extending between the Si pillars 12c and 12d (an example of “fourth region” in the claims).

Next, as illustrated in FIGS. 6DA to 6DC, the mask material layers 14a to 14d and 45a to 45d and the HfO₂ layer 41 surrounding the mask material layer 46A and the N⁺ layers 13a to 13d are etched to form contact holes 47a, 47b, 47c, and 47d. Next, as illustrated in FIGS. 6EA to 6EC, conductor layers 49a, 49b, 49c, and 49d are formed in the contact holes 47a to 47d. A bit line BL1 conductor layer 48a extending in the direction along line Y-Y′ in plan view in contact with the conductor layers 49a and 49c and a bit line BL2 conductor layer 48b extending in the direction along line Y-Y′ in plan view in contact with the conductor layers 49b and 49d are then formed. A SiO₂ layer 50 including voids 51a, 51b, and 51c extending in the direction along line Y-Y′ is then formed between and on both sides of the bit line BL1 conductor layer 48a and the bit line BL2 conductor layer 48b. Thus, as in the first embodiment, a dynamic flash memory is formed on the substrate 10.

FIG. 6F illustrates a schematic structural view of the dynamic flash memory illustrated in FIGS. 6EA to 6EC. The N⁺ layer 11a serving as the source line conductor layer SL is formed so as to extend over the entire surface. The TiN layer 40 connected to the plate line PL is also formed so as to extend over the entire surface. The gate conductor TiN layer 26a connected to the word line WL1 is formed so as to extend between the adjacent Si pillars 12a and 12b in the X direction. Similarly, the gate conductor TiN layer 26b connected to the word line WL2 is formed so as to extend between the adjacent Si pillars 12c and 12d in the X direction. The bit line BL1 connected to the N⁺ layers 13a and 13c and the bit line BL2 connected to the N⁺ layers 13b and 13d are formed in the Y direction orthogonal to the X direction.

In FIGS. 6DA to 6DC, the mask material layers 14a to 14d and 45a to 45d and the HfO₂ layer 41 surrounding the mask material layer 46A and the N⁺ layer 13a to 13d are etched to form the contact holes 47a, 47b, 47c, and 47d; however, contact holes may be formed by removing the mask material layers 14a to 14d and the HfO₂ layer 41 without removing the mask material layer 45a to 45d. The contact holes in this case are formed in the same manner as the contact holes 30a to 30d in FIGS. 5GA to 5GC.

This embodiment provides the following features.

### Feature 1

In this embodiment, as in the first embodiment, the gate TiN layer 40 connected to the plate line PL is formed so as to extend between the Si pillars 12a to 12d in the X and Y directions. This indicates that there is no pattern formed by lithography in the memory cell region. This leads to a lower cost of the mask used and a simpler process.

### Feature 2

In the first embodiment, as illustrated in FIGS. 5EA to 5EC, the SiN layer 27a, serving as a mask material layer, is formed so as to extend between the Si pillars 12a and 12b, and the SiN layer 27b, serving as a mask material layer, is formed so as to extend between the Si pillars 12c and 12d. To form the SiN layers 27a and 27b, the Si pillars 12a and 12b need to be formed close to each other, and the Si pillars 12c and 12d need to be formed close to each other. In contrast, in this embodiment, the mask material layer 46a extending in the direction along line X-X′ so as to overlap the Si pillars 12a and 12b and the mask material layers 45a and 45b in plan view and the mask material layer 46b extending in the direction along line X-X′ so as to overlap the Si pillars 12c and 12d and the mask material layers 45c and 45d in plan view are formed. The TiN layer 42 is then etched using the SiN layers 45a to 45d and the mask material layers 46a and 46b as a mask to form the TiN layers 42a and 42b, serving as word line conductor layers. Thus, the SiN layers 45a to 45d need not be formed so as to extend between the Si pillars 12a and 12b and between the Si pillars 12c and 12d. This facilitates the step of forming the SiN layers 45a to 45d and also facilitates increasing the size of the voids 47a to 47c and 51a to 51c and optimizing, for example, the arrangement thereof.

### Other Embodiments

Although the Si pillars 2 and 12a to 12d are formed in the embodiments of the present invention, semiconductor pillars formed of other semiconductor materials may also be formed. This also applies to other embodiments according to the present invention.

In addition, the N⁺ layers 3a, 3b, 11, and 13 in the first embodiment may be formed of Si containing a donor impurity or another semiconductor material layer. In addition, the N⁺ layers 3a, 3b, 11, and 13 may be formed of different semiconductor material layers. In addition, the N⁺ layers 3a, 3b, 11, and 13 may be formed by an epitaxial crystal growth process or another process. This also applies to other embodiments according to the present invention.

In addition, the mask material layers 14a to 14d illustrated in FIGS. 5AA to 5AC may be replaced by another material layer composed of a single layer or a plurality of layers and containing an organic material or an inorganic material as long as the material used is suitable for the object of the present invention, including, for example, SiO₂ layers, aluminum oxide (Al₂O₃, also referred to as A10) layers, and SiN layers. This also applies to other embodiments according to the present invention.

In addition, as illustrated in FIGS. 5HA to 5HC, the N⁺ layer 11a also serves as a wiring conductor layer for the source line SL. Alternatively, a conductor layer such as a W layer may be formed between the portions of the N⁺ layer 11a under the bottom portions of the Si pillars 12a to 12d and may be used as the source line SL. Alternatively, a conductor layer such as a W layer may be formed on the N⁺ layer 11a outside a region in which many Si pillars 12a to 12d are formed in a two-dimensional array. Alternatively, the portions of the N⁺ layer under the Si pillars 12a and 12b may be isolated from the portions of the N⁺ layer under the Si pillars 12c and 12d, for example, using shallow trench isolation (STI) or a well structure. In this case, a low-resistance conductor layer needs to be formed adjacent to each of the isolated portions of the N⁺ layer.

The thickness and shape of the mask material layers 14a to 14d illustrated in the first embodiment change during the subsequent polishing by CMP, etching by RIE, and cleaning. Such changes cause no problem as long as the mask material layers 14a to 14d are suitable for the object of the present invention. This also applies to other embodiments according to the present invention.

In addition, in FIGS. 5EA to 5EC, the upper ends of the mask material layers 27a and 27b are located at the upper ends of the mask material layers 14a to 14d. Alternatively, the upper ends of the mask material layers 27a and 27b in the perpendicular direction may be located at the side surfaces of the mask material layers 14a to 14d as long as the condition that the side surfaces of the N⁺ layer 13a to 13d are covered is satisfied in the RIE step. This also applies to other embodiments according to the present invention.

In addition, the TiN layer 18 is used as the plate line PL and the gate conductor layer 5a connected to the plate line PL in the first embodiment. Alternatively, the TiN layer 18 may be replaced by a single conductive material layer or a combination of a plurality of conductive material layers. Similarly, the TiN layers 26a and 26b are used as the word line WL and the gate conductor layer 5b connected to the word line WL. Alternatively, the TiN layers 26a and 26b may be replaced by a single conductive material layer or a combination of a plurality of conductive material layers. In addition, the gate TiN layer may be connected on its outside to a wiring metal layer such as a W layer. This also applies to other embodiments according to the present invention.

In addition, the conductor layers 49a, 49b, 49c, and 49d illustrated in FIGS. 6EA to 6EC may be formed of a single metal layer or a plurality of metal layers as a whole or may be formed of an N⁺ layer formed adjacent to the N⁺ layer 13a to 13d, for example, by a selective epitaxial crystal growth process, and covered with a metal layer. This also applies to other embodiments according to the present invention.

In addition, the SiN layers 27a and 27b illustrated in FIGS. 5EA to 5EC are etching mask layers for forming the TiN layers 26a and 26b. The SiN layers 27a and 27b may be replaced by another material layer composed of a single layer or a plurality of layers as long as the material layer functions as an etching mask in this embodiment. This also applies to other embodiments according to the present invention.

In addition, although the HfO₂ layers 17a and 41, serving as gate insulating layers, are formed so as to surround the Si pillars 12a to 12d in the second embodiment, the HfO₂ layers 17a and 41 may each be replaced by another material layer composed of a single layer or a plurality of layers. This also applies to other embodiments according to the present invention.

In FIGS. 6AA to 6AC, the aluminum oxide (AlO) layer 43 is formed on the TiN layer 42 around the N⁺ layers 13a to 13d. The AlO layer 43 may be replaced by another material layer composed of a single layer or a plurality of layers as long as the effect intended in this step can be achieved. This also applies to other embodiments according to the present invention.

In the description with reference to FIGS. 5HA to 5HC, the bit line BL1 conductor layer 32a and the bit line BL2 conductor layer 32b are formed in one step; however, a first conductor layer may first be formed in the contact holes 30a to 30d, and a conductor layer forming the bit line BL1 conductor layer 32a and the bit line BL2 conductor layer 32b may then be formed so as to be connected to the first conductor layer. In addition, in FIGS. 6EA to 6EC, the SiO₂ layer 50 is formed after the bit line BL1 conductor layer 48a and the bit line BL2 conductor layer 48b are formed; however, the bit line BL1 conductor layer 48a and the bit line BL2 conductor layer 48b may be formed after the SiO₂ layer 50 is formed and contact holes are then formed above the N⁺ layer 13a to 13d.

In addition, the shape of the Si pillars 12a to 12d in plan view is circular in the first embodiment. The shape of the Si pillars 12a to 12d in plan view may be, for example, circular, oval, or elongated in one direction. In a logic circuit region formed away from the dynamic flash memory cell region, Si pillars having different shapes in plan view can be formed depending on the logic circuit design. These also apply to other embodiments according to the present invention.

In addition, in FIG. 1, the dynamic flash memory element formed in the Si pillar 2 standing on the substrate 1 in the perpendicular direction has been described. As illustrated in this embodiment, it is sufficient that the dynamic flash memory cell have a structure satisfying the conditions where a group of holes 11 generated by an impact ionization phenomenon are held in the channel region 7. Accordingly, it is sufficient that the channel region 7 have a floating body structure isolated from the substrate 1. Thus, the dynamic flash memory operation described above can be achieved even if the semiconductor base forming the channel region is formed parallel to the substrate 1, for example, using gate-all-around technology (GAA; see, for example, E. Yoshida: “A Capacitorless 1T-DRAM Technology Using Gate-Induced Drain-Leakage (GIDL) Current for Low-Power and High-Speed Embedded Memory,” IEEE IEDM (2006)) and nanosheet technology (see, for example, J. Y. Song, W. Y. Choi, J. H. Park, J. D. Lee, and B-G. Park: “Design Optimization of Gate-All-Around (GAA) MOSFETs,” IEEE Trans. Electron Devices, Vol. 5, No. 3, pp. 186-191, May 2006 and N. Loubet, et al.: “Stacked Nanosheet Gate-All-Around Transistor to Enable Scaling Beyond FinFET,” 2017 IEEE Symposium on VLSI Technology Digest of Technical Papers, T17-5, T230-T231, June 2017), which are a type of SGT. The device structure may also be one using a silicon-on-insulator (SOI) substrate (see, for example, J. Wan, L. Rojer, A. Zaslaysky, and S. Critoloveanu: “A Compact Capacitor-Less High-Speed DRAM Using Field Effect-Controlled Charge Regeneration,” Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI,” IEEE JSSC, Vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, and A. Nitayama: “Floating Body RAM Technology and its Scalability to 32 nm Node and Beyond,” IEEE IEDM (2006); and E. Yoshida: “A Capacitorless 1T-DRAM Technology Using Gate-Induced Drain-Leakage (GIDL) Current for Low-Power and High-Speed Embedded Memory,” IEEE IEDM (2006)). In this device structure, the bottom portion of the channel region is in contact with the insulating layer of the SOI substrate, and the remaining channel region is surrounded by a gate insulating layer and an element isolation insulating layer. This structure also provides a channel region having a floating body structure. Thus, it is sufficient that the dynamic flash memory element provided by this embodiment satisfy the condition that the channel region has a floating body structure. The dynamic flash operation can also be achieved using a structure in which a Fin transistor (see, for example, H. Jiang, N. Xu, B. Chen, L. Zeng, Y. He, G. Du, X. Liu, and X. Zhang: “Experimental investigation of self heating effect (SHE) in multiple-fin SOI FinFETs,” Semicond. Sci. Technol. 29 (2014) 115021 (7pp)) is formed on an SOI substrate as long as the channel region has a floating body structure. These also apply to other embodiments according to the present invention.

In addition, although the source line SL is set to a negative bias to withdraw a group of holes from the channel region 7 serving as the floating body FB during the erase operation in the first and second embodiments, the erase operation may also be performed by setting the bit line BL to a negative bias instead of the source line SL or by setting the source line SL and the bit line BL to a negative bias. Alternatively, the erase operation may be performed under other voltage conditions. This also applies to other embodiments according to the present invention.

In addition, various embodiments of and modifications to the present invention can be made without departing from the broad spirit and scope of the present invention. In addition, the foregoing embodiments are intended to illustrate examples of the present invention and not to limit the scope of the present invention. Any combination of the foregoing embodiments and modifications can be employed. Furthermore, some of the requirements of the foregoing embodiments may be excluded as needed, and such embodiments are also included within the scope of the technical idea of the present invention.

A memory device including a pillar-shaped semiconductor element according to the present invention provides a high-density, high-performance dynamic flash memory.

What is claimed is:

1. A memory device including a pillar-shaped semiconductor element, comprising:
first to fourth semiconductor pillars standing on a substrate in a perpendicular direction, the first and second semiconductor pillars being disposed adjacent to each other on a first line in plan view, the third and fourth semiconductor pillars being disposed adjacent to each other on a second line extending parallel to the first line in plan view;
a first impurity region connected to bottom portions of the first to fourth semiconductor pillars;
a gate insulating layer surrounding the first to fourth semiconductor pillars in the perpendicular direction;
a first gate conductor layer surrounding the gate insulating layer and extending between the first to fourth semiconductor pillars;
a second gate conductor layer surrounding the gate insulating layer, the second gate conductor layer being adjacent to the first gate conductor layer in the perpendicular direction and extending between the first semiconductor pillar and the second semiconductor pillar on the first line;
a third gate conductor layer surrounding the gate insulating layer, the third gate conductor layer being adjacent to the first gate conductor layer in the perpendicular direction, being located at the same height as the second gate conductor layer, and extending between the third semiconductor pillar and the fourth semiconductor pillar on the second line;
second impurity regions in top portions of the first to fourth semiconductor pillars;
a first wiring conductor layer connected to the second impurity regions in the top portions of the first semiconductor pillar and the third semiconductor pillar; and
a second wiring conductor layer connected to the second impurity regions in the top portions of the second semiconductor pillar and the fourth semiconductor pillar,
wherein voltages applied to the first gate conductor layer, the second gate conductor layer, the third gate conductor layer, the first impurity region, and the second impurity regions are controlled to perform a data write operation, a data read operation, and a data erase operation.

2. The memory device including a pillar-shaped semiconductor element according to claim 1, wherein, in plan view,
a first length between two opposing points of intersection of two outer periphery lines of the gate insulating layer surrounding the first semiconductor pillar and the second semiconductor pillar and the first line is smaller than a second length between two opposing points of intersection of two outer periphery lines of the gate insulating layer surrounding the first semiconductor pillar and the third semiconductor pillar and a third line passing through centers of the first semiconductor pillar and the third semiconductor pillar,
the second length is greater than twice a third length that is a thickness of the first gate conductor layer surrounding the first semiconductor pillar on the third line, and
the first length is smaller than twice the third length.

3. The memory device including a pillar-shaped semiconductor element according to claim 1, wherein
a wiring line connected to the first impurity region is a source line, a wiring line connected to the second impurity regions is a bit line, and when one of a wiring line connected to the first gate conductor layer and a wiring line connected to the second gate conductor layer is a word line, the other of the wiring line connected to the first gate conductor layer and the wiring line connected to the second gate conductor layer is a first drive control line, and
voltages applied to the source line, the bit line, the first drive control line, and the word line are controlled to perform the data write operation, the data read operation, and the data erase operation.

4. The memory device including a pillar-shaped semiconductor element according to claim 1, wherein a first gate capacitance between the first gate conductor layer and the first semiconductor pillar is greater than a second gate capacitance between the second gate conductor layer and the first semiconductor pillar.

5. The memory device including a pillar-shaped semiconductor element according to claim 1, wherein a first void is present between the second gate conductor layer and the third gate conductor layer in plan view.

6. The memory device including a pillar-shaped semiconductor element according to claim 1, wherein a second void is present between the first wiring conductor layer and the second wiring conductor layer.

7. The memory device including a pillar-shaped semiconductor element according to claim 1, wherein the gate insulating layer extends between the side surfaces of the first to fourth semiconductor pillars, the first gate conductor layer, the second gate conductor layer, and the third gate conductor layer.

8. The memory device including a pillar-shaped semiconductor element according to claim 1, wherein, in plan view, both a first length between two opposing points of intersection of two outer periphery lines of the gate insulating layer surrounding the first semiconductor pillar and the second semiconductor pillar and the first line and a second length between two opposing points of intersection of two outer periphery lines of the gate insulating layer surrounding the first semiconductor pillar and the third semiconductor pillar and a third line passing through centers of the first semiconductor pillar and the third semiconductor pillar are greater than twice a third length that is a thickness of the first gate conductor layer surrounding the first semiconductor pillar on the third line.

9. The memory device including a pillar-shaped semiconductor element according to claim 8, wherein
in plan view, the second gate conductor layer includes a first region surrounding the first semiconductor pillar and the second semiconductor pillar at equal width and a second region extending between the first semiconductor pillar and the second semiconductor pillar on the first line, and
in plan view, the third gate conductor layer includes a third region surrounding the third semiconductor pillar and the fourth semiconductor pillar at equal width and a fourth region extending between the third semiconductor pillar and the fourth semiconductor pillar on the second line.

10. The memory device including a pillar-shaped semiconductor element according to claim 1, wherein the first gate conductor layer, the second gate conductor layer, the third gate conductor layer, the first impurity region, and the second impurity regions are configured such that
the voltages applied to the first gate conductor layer, the second gate conductor layer, the third gate conductor layer, the first impurity region, and the second impurity regions are controlled to perform a data write operation of holding a group of holes generated by an impact ionization phenomenon or a gate-induced drain leakage current in any or all of the first to fourth semiconductor pillars, and
the voltages applied to the first gate conductor layer, the second gate conductor layer, the third gate conductor layer, the first impurity region, and the second impurity regions are controlled to perform a data erase operation of removing the group of holes from any or all of the first to fourth semiconductor pillars.

11. The memory device including a pillar-shaped semiconductor element according to claim 1, wherein one or both of the first gate conductor layer and the second and third gate conductor layers are split into a plurality of segments in plan view.

12. The memory device including a pillar-shaped semiconductor element according to claim 1, wherein the first gate conductor layer is split into a plurality of segments in the perpendicular direction.

13. The memory device including a pillar-shaped semiconductor element according to claim 1, wherein the second gate conductor layer and the third gate conductor layer are split into a plurality of segments at the same height in the perpendicular direction.
